(19) United States
(12) Patent Application Publication
(10) Pub. No.: US 2021/0403337 A1
(43) Pub. Date: Dec. 30, 2021

(54) YTTRIUM OXIDE BASED COATING AND BULK COMPOSITIONS

(71) Applicant: Applied Materials, Inc., Santa Clara, CA (US)

(72) Inventors: Christopher Laurent Beaudry, San Jose, CA (US); Vahid Firouzdor, Hillsborough, CA (US); Joseph Frederick Sommers, San Jose, CA (US); Trevor Edward Wilantewicz, Sunnyvale, CA (US); Hyun-Ho Doh, San Ramon, CA (US); Joseph Frederick Behnke, San Jose, CA (US)

(21) Appl. No.: 17/359,343

(22) Filed: Jun. 25, 2021

Related U.S. Application Data
(60) Provisional application No. 63/045,900, filed on Jun. 30, 2020.

(51) Int. Cl. C01F 17/34; C23C 14/08; C23C 14/22; C23C 4/11; C23C 4/134

(52) U.S. Cl. CPC C01F 17/34; C23C 14/08; C23C 4/134; C23C 4/11; C23C 14/221

(57) ABSTRACT

Described herein is a plasma resistant protective coating composition and bulk composition that provides enhanced erosion and corrosion resistance upon the coating composition's or the bulk composition's exposure to harsh chemical environment (such as hydrogen based and/or halogen based chemistries) and/or upon the coating composition's or the bulk composition's exposure to high energy plasma. Also described herein is a method of coating an article with a plasma resistant protective coating using electronic beam ion assisted deposition, physical vapor deposition, or plasma spray. Also described herein is a method of processing wafer, which method exhibits a reduced number of yttrium based particles.

### RELATED APPLICATIONS

This application claims priority to U.S. Provisional Patent Application No. 63/045,900, filed Jun. 30, 2020, which is herein incorporated by reference in its entirety.

### TECHNICAL FIELD

Embodiments of the present disclosure relate, in general, to a yttrium oxide based protective coating and bulk compositions for enhanced defect performance in semiconductor processing applications.

### BACKGROUND

In the semiconductor industry, devices are fabricated by a number of manufacturing processes producing structures of an ever-decreasing size. As device geometries shrink, controlling the process uniformity and repeatability become much more challenging.

Existing manufacturing processes expose semiconductor processing chamber components (also referred to as process chamber components) to high energy aggressive plasma and/or corrosive environment which may be harmful to the integrity of the semiconductor processing chamber components and may further contribute to the challenge of controlling process uniformity and repeatability.

Hence, certain semiconductor processing chamber components (e.g., liners, doors, lids, and so on) are coated with yttrium based protective coatings or are made of yttrium based bulk composition. Yttria (Y₂O₃) is commonly used in etch chamber components due to its good erosion and/or sputtering resistance in aggressive plasma environment.

It would be advantageous to arrive at a protective coating and bulk compositions that provide both physical resistance to sputtering occurring from high energy aggressive plasma and chemical resistance to corrosion occurring from corrosive environments.

### BRIEF SUMMARY OF EMBODIMENTS

In certain embodiments, the instant disclosure is directed to a ceramic body consisting of a single phase bulk crystalline yttrium aluminum garnet (YAG). The single phase bulk crystalline YAG includes yttrium oxide at a molar concentration ranging from about 35 mole % to 40 mole % and aluminum oxide at a molar concentration ranging from 60 mole % to 65 mole %. The single phase bulk crystalline YAG has a density of about 98% or greater and a hardness greater than about 10 GPa.

In certain embodiments, the instant disclosure is directed to a method for coating a chamber component. The method includes performing electron beam ion assisted deposition (e-beam IAD) to deposit a plasma resistant protective coating. The plasma resistant protective coating includes a single phase amorphous blend of yttrium oxide at a molar concentration ranging from about 35 mole % to about 95 mole % and aluminum oxide at a molar concentration ranging from about 5 mole % to about 65 mole %. The plasma resistant protective coating has a porosity of essentially 0% (e.g., less than 0.1%) and an adhesion strength greater than about 25 MPa.

In certain embodiments, the instant disclosure is directed to a method for coating a chamber component. The method includes performing plasma spray or physical vapor deposition (PVD) to deposit a plasma resistant protective coating on a chamber component. The plasma resistant protective coating includes a blend of yttrium oxide at a molar concentration ranging from about 35 mole % to about 95 mole % and aluminum oxide at a molar concentration ranging from about 5 mole % to about 65 mole %. The plasma resistant protective coating is at least about 90% amorphous. The average total number of yttrium based particles released from the plasma resistant protective coating upon exposure to a corrosive chemistry is less than 3 per 500 radiofrequency hours.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of one embodiment of a processing chamber.

FIG. 2 illustrates a phase diagram of alumina and yttria.

FIG. 3 illustrates cross sectional side views of articles (e.g., lids) covered by one or more protective coatings.

FIG. 4A illustrates a perspective view of a chamber lid having a protective coating or bulk composition according to embodiments.

FIG. 4B illustrates a cross-sectional side view of a chamber lid having a protective coating or bulk composition according to embodiments.

FIGS. 5A1, 5A2, 5B1, and 5B2 illustrate chemical resistance of various bulk composition subjected to accelerated chemical stress testing.

FIG. 6A depicts a deposition mechanism applicable to a variety of deposition techniques utilizing energetic particles such as ion assisted deposition (IAD).

FIG. 6B depicts a schematic of an IAD deposition apparatus.

FIGS. 7A1, 7A2, 7B1, 7B2, 7C1, 7C2, 7D1, and 7D2 illustrate chemical resistance of various plasma resistant protective coating deposited by IAD upon being subjected to accelerated chemical stress testing.

FIG. 8 illustrates a schematic of a physical vapor deposition technique that may be utilized to deposit a plasma resistant protective coating according to an embodiment.

FIG. 9 depicts a schematic of a plasma spray deposition technique that may be utilized to deposit a plasma resistant protective coating according to an embodiment.

FIG. 10A1, 10A2, 10B1, 10B2, 10C1, 10C2, 10D1, and 10D2 illustrate chemical resistance of various plasma resistant protective coatings deposited by plasma spray upon being subjected to accelerate chemical stress testing.

FIG. 11 illustrates a method for coating a chamber component with a plasma resistant protective coating according to embodiments.

FIG. 12 depicts a method for processing a wafer in a processing chamber that includes at least one chamber component coated with a plasma resistant protective coating or having a bulk composition according to an embodiment.

FIG. 13A shows total yttrium-based particles from a lid coated with a plasma resistant protective coating according to embodiments during a 770 RFhrs chamber marathon running aggressive chemistry.

FIG. 13B shows total yttrium-based particles from a nozzle coated with a plasma resistant protective coating according to embodiments during a 460 RFhrs chamber marathon running aggressive chemistry.

FIG. 13C shows total yttrium-based particles from a kit of a lid and a nozzle coated with a plasma resistant protective coating according to embodiments during processing in aggressive chemistry as compared to a kit of a lid and a nozzle coated with a Y₂O₃—ZrO₂ solid solution.

FIG. 14 shows total yttrium-based particles from a kit of a lid, a nozzle, and a liner coated with a plasma resistant protective coating according to embodiments during processing in aggressive chemistry as compared to kit of lid, nozzle, and liner coated with various comparative yttrium based compositions.

FIG. 15 depicts the normalized erosion rate (nm/RFhr) of a comparative bulk YAG composition (bulk YAG), a first optimized bulk YAG composition according to an embodiment (Bulk YAG1 (Optimized)) prepared via Field Assisted Sintering (FAS), and a second optimized bulk YAG composition according to an embodiment (Bulk YAG2 (Optimized)) prepared according to Hot Isotactic Pressing (HIP).

### DETAILED DESCRIPTION OF EMBODIMENTS

Semiconductor manufacturing processes expose semiconductor process chamber components to high energy aggressive plasma environments and to corrosive environments. To protect the process chamber components from these aggressive environments, chamber components are coated with protective coatings or are made of bulk compositions that are resistant to such aggressive plasma environments and to corrosive environments.

Yttria (Y₂O₃) is commonly used in coatings of chamber components (e.g., etch chamber components) for its good erosion resistance. Despite its good erosion resistance, yttria is not chemically stable in aggressive etch chemistries. Radicals like Fluorine, Chlorine and Bromide easily attack yttria chemically, contributing to the formation of yttrium-based particles. yttrium-based particles contribute to defects in etch applications. Hence, various industries (e.g., logic industry) have begun to set tight specifications for yttrium-based defects on product wafers.

To meet these tight specifications, it is beneficial to identify protective coating compositions and bulk compositions that provide both physical resistance to sputtering occurring due to high energy aggressive plasma and chemical resistance occurring due to chemical attacks by aggressive chemical environments.

In this disclosure a plasma resistant protective coating composition and bulk compositions have been identified having improved chemical stability compared to pure yttria (Y₂O₃) and other yttrium-based materials while also maintaining physical resistance to high energy aggressive plasma compared to pure alumina (Al₂O₃).

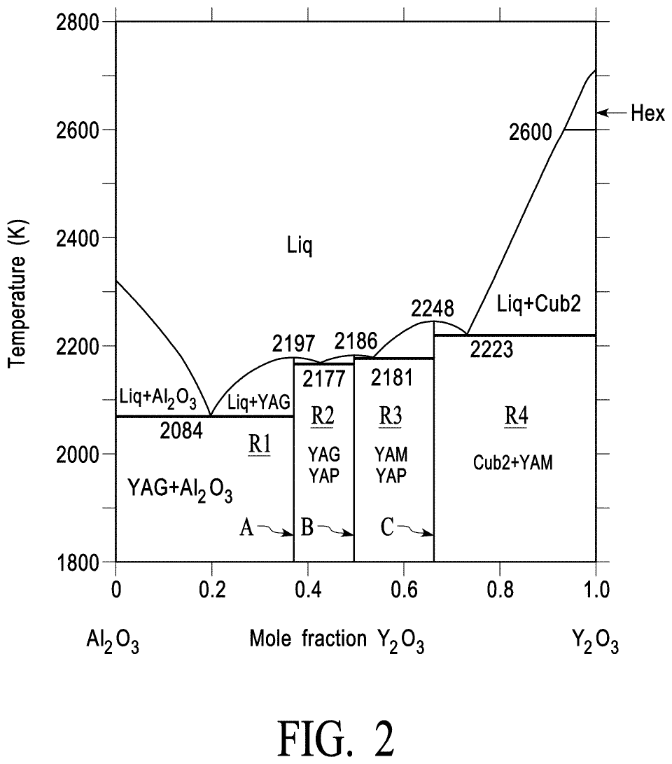

In certain embodiments, the protective coating described herein is a corrosion and erosion resistant coating that includes a substantially amorphous (i.e., at least about 90% amorphous) blend of aluminum oxide and yttrium oxide. In certain embodiments, the protective coating is completely amorphous (i.e., 100% amorphous). Due to the substantially amorphous nature of the protective coating, there may be more flexibility in tuning the amounts of alumina and yttria to achieve optimal chemical resistance (e.g., to harsh chemical environments) and physical resistance (e.g., to harsh plasma environments), since the compositions are not constrained to the bond arrangements of a crystalline composition or to the phases depicted in the alumina-yttria phase diagram shown in FIG. 2.

Without being construed as limiting, it is believed that introducing more of the aluminum-based component into the coating renders the coating more chemically resistant to harsh chemical environments (e.g., acidic environments, hydrogen based environments, and halogen based environments) and that the yttrium-based component in the coating provides the coating the physical resistance to high energy plasma environment.

In one embodiment, the protective coating described herein may have the chemical composition of yttrium aluminum garnet (YAG) or be near the chemical composition of YAG (in terms of the amount of yttrium, aluminum, and oxygen in the composition) but have mechanical properties (e.g., density, porosity, hardness, breakdown voltage, roughness, hermeticity, adhesion strength, crystallinity/amorphous nature, and so on) and chemical properties (e.g., chemical resistivity) that provide for enhanced chemical resistance at aggressive chemical environment (e.g., aggressive halogen and/or hydrogen acidic environments) and/or enhanced plasma resistance as compared to other yttrium based coatings and/or as compared to other YAG coatings prepared and/or deposited differently from the instant disclosure.

Plasma resistant protective coatings described herein may be deposited by ion assisted deposition, physical vapor deposition, or plasma spray. The deposition technique may be chosen and optimized to achieve plasma resistant protective coatings having certain properties, such as high density, very low internal and/or surface porosity (or no porosity), amorphous content, adhesion strength, roughness, breakdown voltage, hermeticity, hardness, flexural strength, chemical stability, and physical stability to name a few.

Plasma resistant protective coatings described herein may be coated on any number of chamber components, and may be particularly suitable for coating a lid and/or a nozzle and/or a liner. Processing wafers in a processing chamber having at least one chamber component coated with the plasma resistant protective coatings described herein significantly reduces the number of yttrium based particles generated during processing, reduces wafer defectivity due to the existence of yttrium based particles, reduces variability across a plurality of processes with respect to yttrium based particle formation and defectivity associated therewith, increases reliability, increases accuracy, increases reproducibility, increases predictability, increases yield, increases throughput, and reduces cost.

In certain embodiments, the instant disclosure is directed to plasma resistant bulk compositions having improved chemical stability compared to pure yttria (Y₂O₃) and other yttrium-based materials while also maintaining physical resistance to high energy aggressive plasma compared to pure alumina (Al₂O₃).

In certain embodiments, any chamber component and in particular lids and/or nozzles and/or liners include a ceramic body consisting of a single phase bulk crystalline yttrium aluminum garnet (YAG), wherein the single phase bulk crystalline YAG comprises yttrium oxide at a molar concentration ranging from 35 mole % to 40 mole % and aluminum oxide at a molar concentration ranging from 60 mole % to 65 mole %, wherein the single phase bulk crystalline YAG has a density of about 98% or greater and a hardness greater than about 10 GPa. The single phase bulk crystalline YAG disclosed in embodiments has shown to be particularly effective, and in particular has been shown to be more effective at chemical resistivity and/or plasma erosion resistance than even other examples of bulk YAG ceramics. The bulk ceramic body is completely crystalline in embodiments. The bulk composition may be the result of a two-step sintering process that includes hot isotactic pressing (HIP). The process may be optimized to bulk compositions having certain properties, such as high density, very low porosity (or essentially no porosity), hardness, chemical stability, and physical stability to name a few.

Processing wafers in a processing chamber having at least one chamber component made from bulk compositions described herein significantly reduces the number of yttrium based particles generated during processing, reduces wafer defectivity due to the existence of yttrium based particles, reduces variability across a plurality of processes with respect to yttrium based particle formation and defectivity associated therewith, increases reliability, increases accuracy, increases reproducibility, increases predictability, increases yield, increases throughput, and reduces cost, even in comparison to other bulk YAG ceramics.

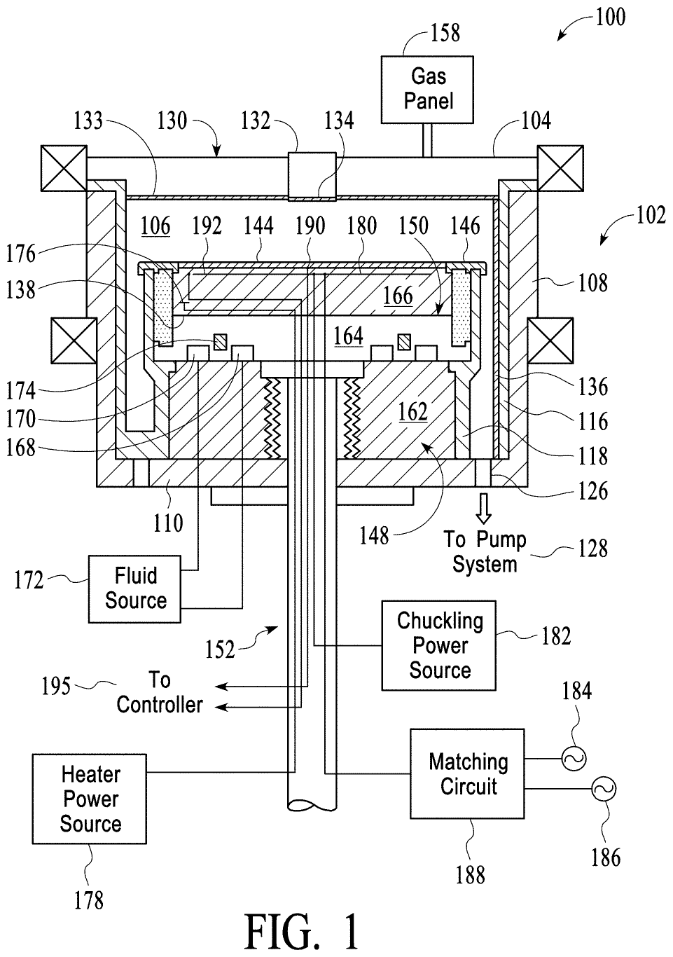

FIG. 1 is a sectional view of a semiconductor processing chamber 100 having one or more chamber components that are either coated with a plasma resistant protective coating composition in accordance with embodiments of the present disclosure or made of a bulk composition in accordance with embodiments of the present disclosure. The processing chamber 100 may be used for processes in which aggressive plasma environment and/or aggressive chemical environment is provided. For example, the processing chamber 100 may be a chamber for a plasma etch reactor (also known as a plasma etcher), a plasma cleaner, and so forth.

Examples of chamber components that may include a plasma resistant protective coating include a substrate support assembly 148, an electrostatic chuck (ESC) 150, a ring (e.g., a process kit ring or single ring), a chamber wall, a base, a gas distribution plate, a showerhead, a liner, a liner kit, a shield, a plasma screen, a flow equalizer, a cooling base, a chamber viewport, a chamber lid 130, a nozzle, and so on. Any of these chamber components may also be made of a bulk composition that is plasma resistant and chemically resistant according to embodiments described herein. In one particular embodiment, chamber lid 130 and/or a liner 116 or 118 and/or nozzle 132 are independently either coated with a plasma resistant protective coating or are made of a bulk material that is plasma resistant and chemically resistant according to embodiments described herein.

In certain embodiments, the plasma resistant protective coating, which is described in greater detail below, is a blend of yttrium oxide at a molar concentration ranging from about 35 mole % to about 95 mole % and aluminum oxide at a molar concentration ranging from about 5 mole % to about 65 mole %. The plasma resistant protective coating may be deposited by ion assisted deposition (IAD), such as electron beam ion assisted deposition (e-beam IAD), physical vapor deposition (PVD), and plasma spray. Depending on the deposition technique, the plasma resistant protective coating is at least about 90% amorphous, at least about 92% amorphous, at least about 94% amorphous, at least about 96% amorphous, at least about 98% amorphous, or a single phase 100% amorphous.

In certain embodiments, the plasma resistant protective coating includes yttrium oxide at a molar concentration of 35 mole % to 40 mole % and aluminum oxide at a molar concentration of 60 mole % to 65 mole %. In certain embodiments, the plasma resistant protective coating includes yttrium oxide at a molar concentration of 37 mole % to 38 mole % and aluminum oxide at a molar concentration of 62 mole % to 63 mole %. In certain embodiments, the molar concentration of yttrium oxide and aluminum oxide in the plasma resistant protective coating adds up to 100 mole %.

In certain embodiments, the plasma resistant protective coating includes yttrium oxide at a molar concentration ranging from any of about 35 mole %, about 35.5 mole %, about 36 mole %, about 36.5 mole %, about 37 mole %, or about 37.5 mole % to any of about 38 mole %, about 38.5 mole %, about 39 mole %, about 39.5 mole %, about 40 mole %, about 45 mole %, about 50 mole %, about 55 mole %, about 60 mole %, about 65 mole %, about 70 mole %, about 75 mole %, about 80 mole %, about 85 mole %, about 90 mole %, or about 95 mole %, or any single value therein or any sub-range therein.

In certain embodiments, the plasma resistant protective coating includes aluminum oxide at a molar concentration ranging from any of about 5 mole %, about 10 mole %, about 15 mole %, about 20 mole %, about 25 mole %, about 30 mole %, about 35 mole %, about 40 mole %, about 45 mole %, about 50 mole %, about 55 mole %, about 60 mole %, about 60.5 mole %, about 61 mole %, about 61.5 mole %, or about 62 mole % to any of about 62.5 mole %, about 63 mole %, about 63.5 mole %, about 64 mole %, about 64.5 mole %, or about 65 mole %, or any single value therein or any sub-range therein.

In certain embodiments, the plasma resistant protective coating described herein consists of or consists essentially of a single phase amorphous blend of aluminum oxide and yttrium oxide, wherein the aluminum oxide is present in the plasma resistant protective coating at a molar concentration ranging from about 5 mole % to about 65 mole %, from 60 mole % to 65 mole %, or from 62 mole % to 63 mole % and the yttrium oxide is present in the plasma resistant protective coating at a molar ranging from about 35 mole % to about 95 mole %, from 35 mole % to 40 mole %, or from 37 mole % to 38 mole %.

In certain embodiments, the plasma resistant protective coating described herein consists of or consists essentially of at least about 90% amorphous blend of aluminum oxide and yttrium oxide, wherein the aluminum oxide is present in the plasma resistant protective coating at a molar concentration ranging from about 5 mole % to about 65 mole %, from 60 mole % to 65 mole %, or from 62 mole % to 63 mole % and the yttrium oxide is present in the plasma resistant protective coating at a molar ranging from about 35 mole % to about 95 mole %, from 35 mole % to 40 mole %, or from 37 mole % to 38 mole %.

In certain embodiments, the bulk composition, which is described in greater detail below, consists of a single phase bulk crystalline yttrium aluminum garnet (YAG) that includes yttrium oxide at a molar concentration ranging from 35 mole % to 40 mole % and aluminum oxide at a molar concentration ranging from 60 mole % to 65 mole %. In certain embodiments, the bulk composition is highly dense and has a density of about 98% or greater, about 98.5% or greater, about 99% or greater, about 99.5% or greater, or about 100% (e.g., approximately 0% porosity). In certain embodiments, the bulk composition has a hardness of about 10 GPa or greater, about 11 GPa or greater, about 12 GPa or greater, or about 13 GPa or greater. In certain embodiments, certain properties and characteristics of the bulk composition described herein (such as, without limitations, density, hardness, and the like) may be modified to vary by up to 30% (e.g., 10 GPa±30% would range from 7 GPa to 13 GPa), up to 25% (e.g., 10 GPa±25% would range from 7.5 GPa to 12.5 GPa), up to 20% (e.g., 10 GPa±20% would range from 8 GPa to 12 GPa), up to 15% (e.g., 10 GPa±15% would range from 8.5 GPa to 11.5 GPa), up to 10% (e.g., 10 GPa±10% would range from 9 GPa to 11 GPa), or up to 5% (e.g., 10 GPa±5% would range from 9.5 GPa to 10.5 GPa), in certain embodiments. Accordingly, the described values for these material properties should be understood as example achievable values.

In certain embodiments, the single phase bulk crystalline composition is the result of a two-step sintering process that includes hot isotactic pressing (HIP). In certain embodiments, the sintering process includes compressing raw ceramic powders into a form (similar to ceramic processing), compressing them into a sheet, and firing the ceramics to promote full densification. The sintering process may be controlled to attain optimized conditions and bulk composition properties, such as, without limitation, a high yield, a high density, improved hardness, improved polish, surface roughness, improved chemical stability, improved physical stability, precise and accurate composition, to name a few.

In certain embodiments, the bulk composition consists of a single phase bulk crystalline yttrium aluminum garnet (YAG) that includes yttrium oxide at a molar concentration ranging from any of about 35 mole %, about 35.5 mole %, about 36 mole %, about 36.5 mole %, about 37 mole %, or about 37.5 mole % to any of about 38 mole %, about 38.5 mole %, about 39 mole %, about 39.5 mole %, or about 40 mole %, or any single value therein or any sub-range therein.

In certain embodiments, the bulk composition consists of a single phase bulk crystalline YAG that includes aluminum oxide at a molar concentration ranging from any of about 60 mole %, about 60.5 mole %, about 61 mole %, about 61.5 mole %, or about 62 mole % to any of about 62.5 mole %, about 63 mole %, about 63.5 mole %, about 64 mole %, about 64.5 mole %, or about 65 mole %, or any single value therein or any sub-range therein.

In certain embodiments, the bulk composition described herein consists of a single phase bulk crystalline YAG that consists of or consists essentially of aluminum oxide at a molar concentration ranging from any of about 60 mole %, about 60.5 mole %, about 61 mole %, about 61.5 mole %, or about 62 mole % to any of about 62.5 mole %, about 63 mole %, about 63.5 mole %, about 64 mole %, about 64.5 mole %, or about 65 mole % and of yttrium oxide at a molar concentration ranging from any of about 35 mole %, about 35.5 mole %, about 36 mole %, about 36.5 mole %, about 37 mole %, or about 37.5 mole % to any of about 38 mole %, about 38.5 mole %, about 39 mole %, about 39.5 mole %, or about 40 mole %.

In certain embodiments, bulk composition described are greater than about 90% crystalline, greater than about 92% crystalline, greater than about 94% crystalline, greater than about 96% crystalline, greater than about 98% crystalline, greater than about 99% crystalline, or about 100% crystalline as measured by X-Ray Diffraction (XRD).

Crystalline compositions of alumina and yttria follow the solid lines depicted in the alumina-yttria phase diagram depicted in FIG. 2. As such, a bulk composition of crystalline yttrium aluminum garnet (YAG), at a temperature below about 2177 K, would be constrained to the alumina and yttria amounts corresponding to solid line A in FIG. 2 (about 37-38 mole % yttria and about 62-63 mole % alumina). Similarly, a bulk composition of crystalline yttrium aluminum perovskite (YAP), at a temperature below about 2181 K, would be constrained to the alumina and yttria amounts corresponding to solid line B in FIG. 2 (about 50 mole % yttria and about 50 mole % alumina). A bulk composition of crystalline yttrium aluminum monoclinic (YAM), at a temperature below about 2223 K, would be constrained to the alumina and yttria amounts corresponding to solid line C in FIG. 2 (about 65 mole % yttria and about 35 mole % alumina). If additional alumina or yttria is added to a bulk composition that corresponds to any one of solid lines A, B, or C, a mixture of two crystalline phases forms. For instance, from solid line A and below a temperature of about 2084 K, adding more alumina brings about a mixture of crystalline YAG and crystalline alumina (region R1), while adding more yttria brings about a mixture of crystalline YAG and crystalline YAP (region R2). Similarly, from solid line B and below a temperature of about 2177 K, adding more alumina brings about a mixture of crystalline YAG and crystalline YAP (region R2), while adding more yttria brings about a mixture of crystalline YAM and crystalline YAP (region R3). From solid line C and below a temperature of about 2181 K, adding more alumina brings about a mixture of crystalline YAM and crystalline YAP (region R3), while adding more yttria brings about a mixture of crystalline YAM and cubic yttrium aluminum (Cub2) (region R4).

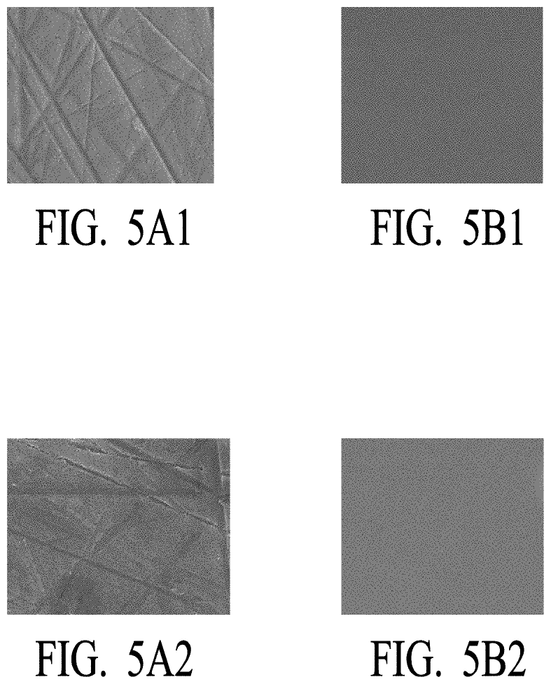

In certain embodiments, the bulk compositions described herein provide a greater chemical resistance to corrosive chemistry (e.g., hydrogen based chemistry, halogen based chemistry, or a mixture thereof) as compared to other yttrium based bulk compositions, as illustrated in FIGS. 5A1, 5A2, 5B1, and 5B2. In certain embodiments, the single phase bulk crystalline YAG disclosed in embodiments has shown to provide a greater chemical resistance to corrosive chemistry (e.g., hydrogen based chemistry, halogen based chemistry, or a mixture thereof) as compared to other examples of bulk YAG ceramics.

FIGS. 5A1 and 5A2 depict a comparative bulk YAG prior to exposure (FIG. 5A1) and after exposure (FIG. 5A2) to an aggressive acid soak for 60 minutes in a concentrated halogen based acid (e.g., HCl, HF, HBr). Medium chemical damage is observed in bulk YAG after the accelerated chemical resistance test. For instance, in FIG. 5A2, about 10% of the comparative bulk YAG was attacked. In other words, in FIG. 5A2, excluding the scratches, there is a general change in appearance indicative of chemical attack. FIGS. 5B1 and 5B2 depict bulk YAG, according to an embodiment, prior to exposure (FIG. 5B1) and after exposure (FIG. 5B2) to an aggressive acid soak for 60 minutes in a concentrated halogen based acid (e.g., HCl, HF, HBr). No damage is observed in bulk YAG after the accelerated chemical resistance test. The comparative bulk YAG depicted in FIGS. 5A1 and 5A2 had a density of about 92-98% and a hardness of about 9.3 GPa.

The inventive bulk YAG depicted in FIGS. 5B1 and 5B2 was prepared using a two step sintering process (e.g., including hot isostatic sintering process), had a density of about 98% or greater and a hardness of about 13 GPa (i.e., about 33% improvement in hardness compared to the baseline comparative YAG of FIGS. 5A1 and 5A2). The inventive bulk YAG depicted in FIGS. 5B1 and 5B2 had increased yield, had a bottom surface roughness of about 10% or less (compared to about 94% in the comparative bulk YAG), had a side surface roughness of about 15% or less (compared to about 98% in the comparative bulk YAG), exhibited improved hole quality evidenced by improved roughness of less than 50 μm (compared to 50 μm with the comparative bulk YAG), and had a significantly reduced porosity compared to the comparative bulk YAG. These properties (e.g., surface roughness and improved hole quality) were measured using profilometry. Furthermore, upon subjecting the inventive bulk YAG to 100 radiofrequency hours of processing in TiOₓ etching environment, no yttrium based particles were observed, exhibiting enhanced performance in reducing part related particles.

In certain embodiments, plasma resistant protective coating compositions described herein are greater than about 90% amorphous, greater than about 92% amorphous, greater than about 94% amorphous, greater than about 96% amorphous, greater than about 98% amorphous, greater than about 99% amorphous, or about 100% amorphous as measured by X-Ray Diffraction (XRD). In certain embodiments, the plasma resistant protective coating described herein has no crystalline areas therein. As such, the plasma resistant protective coatings described herein provide the flexibility of incorporating a greater amount of aluminum oxide and/or a greater amount of yttrium oxide without being constrained to the solid lines and compositional mixtures depicted in the alumina-yttria phase diagram depicted in FIG. 2.

For instance, aluminum oxide is believed to provide for a greater chemical stability to harsh chemical environments (such as acidic environment, hydrogen based environments, and halogen based environments) so more aluminum oxide may be added to form a coating composition that has improved chemical stability in harsh chemical environments. On the other hand, yttrium oxide is believed to provide for a greater physical stability to high energy plasma so more yttrium oxide may be added to form a coating composition that has improved physical stability in high energy plasma. Due to the amorphous nature of the coatings compositions, it is possible to tune the amount of alumina and yttria in the protective coating while maintaining a substantially single amorphous phase. This is believed to be possible due to the amorphous nature of the coatings in which bond links between atoms can and do vary (as opposed to bond links in crystalline compositions that are constrained to the alumina-yttria phase diagram of FIG. 2).

In other words, in certain embodiments, adding alumina to an amorphous protective coating having a composition of alumina and yttria that corresponds to solid line A, would include a single phase amorphous blend of yttria and alumina corresponding to any of the compositions in region R1 (ranging from above 62 or 63 mole % alumina to below 100 mole % alumina and from above 0 mole % yttria to below 37 or 38 mole % yttria), rather than a mixture of two crystalline phases of YAG and alumina as with the crystalline bulk composition. In certain embodiments, the single phase amorphous blend of yttria and alumina, having a composition in region R1, may be homogenous or substantially homogenous.

Similarly, adding alumina to an amorphous protective coating having a composition of alumina and yttria that corresponds to solid line B, would include a single phase amorphous blend of yttria and alumina corresponding to any of the compositions in region R2 (ranging from above 50 mole % alumina to below 62 or 63 mole % alumina and from above 37 or 38 mole % yttria to below 50 mole % yttria), rather than a mixture of two crystalline phases of YAG and YAP as with the crystalline bulk composition. In certain embodiments, the single phase amorphous blend of yttria and alumina, having a composition in region R2, may be homogenous or substantially homogenous.

Likewise, adding alumina to an amorphous protective coating having a composition of alumina and yttria that corresponds to solid line C, would include a single phase amorphous blend of yttria and alumina corresponding to any of the compositions in region R3 (ranging from above 35 mole % alumina to below 50 mole % alumina and from above 50 mole % yttria to below 65 mole % yttria), rather than a mixture of two crystalline phases of YAM and YAP as with the crystalline bulk composition. In certain embodiments, the single phase amorphous blend of yttria and alumina, having a composition in region R3, may be homogenous or substantially homogenous.

In certain embodiments, adding yttria to an amorphous protective coating having a composition of alumina and yttria that corresponds to solid line C, would include a single phase amorphous blend of yttria and alumina corresponding to any of the compositions in region R4 (ranging from above 0 mole % alumina to below 35 mole % alumina and from above 65 mole % yttria to below 100 mole % alumina), rather than a mixture of two crystalline phases of YAM and Cub2 as with the crystalline bulk composition. In certain embodiments, the single phase amorphous blend of yttria and alumina, having a composition in region R4, may be homogenous or substantially homogenous.

In one embodiment, the protective coating described herein may have the chemical composition of yttrium aluminum garnet (YAG) or be near the chemical composition of YAG (in terms of the amount of yttrium, aluminum, and oxygen in the composition) but have mechanical properties (e.g., density, porosity, hardness, breakdown voltage, roughness, hermeticity, adhesion strength, crystallinity/amorphous nature, and so on) and/or chemical properties (e.g., chemical resistivity) that provide for enhanced chemical resistance at aggressive chemical environment (e.g., aggressive halogen and/or hydrogen acidic environments) and/or enhanced plasma resistance as compared to other yttrium based coatings and/or as compared to other YAG coatings prepared and/or deposited differently from the instant disclosure.

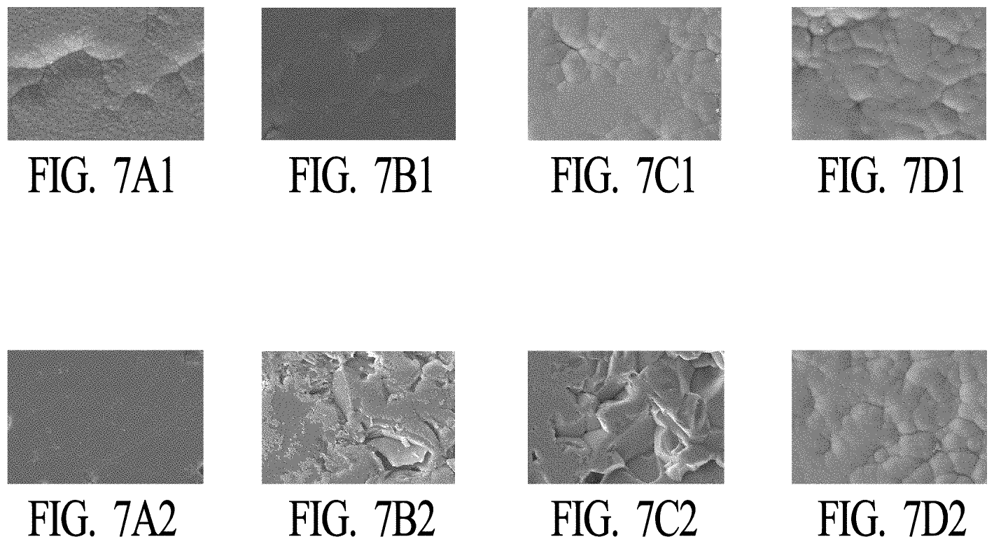

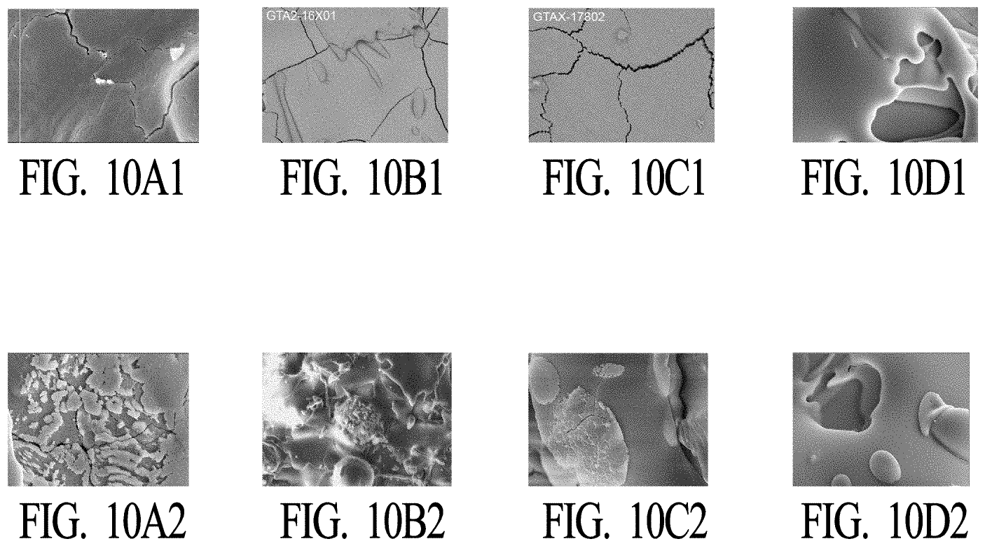

In certain embodiments, the plasma resistant protective coatings described herein provide a greater chemical resistance as compared to other yttrium based coating compositions, prepared using the same process, as described in detail with respect to FIGS. 7 and 10 below.

The plasma resistant protective coating may be an e-beam IAD deposited coating, a PVD deposited coating, or a plasma spray deposited coating applied over different ceramics including oxide based ceramics, nitride based ceramics and/or carbide based ceramics. Examples of oxide based ceramics include SiO₂ (quartz), Al₂O₃, Y₂O₃, and so on. Examples of carbide based ceramics include SiC, Si—SiC, and so on. Examples of nitride based ceramics include AN, SiN, and so on. E-beam IAD coating plug material can be calcined powders, preformed lumps (e.g., formed by green body pressing, hot pressing, and so on), a sintered body (e.g., having 50-100% density), or a machined body (e.g., can be ceramic, metal, or a metal alloy).

Returning to FIG. 1, as illustrated, the lid 130, nozzle 132, and liner 116 each have a plasma resistant protective coating 133, 134, and 136, respectively, in accordance with one embodiment. In certain embodiments, nozzle 132 is made of any of the bulk compositions described herein. In certain embodiments, the nozzle is made exclusively (i.e., 100% of the nozzle) is made of a bulk composition consisting of a single phase bulk crystalline yttrium aluminum garnet (YAG) that includes: 1) yttrium oxide at a molar concentration ranging from any of about 35 mole %, about 35.5 mole %, about 36 mole %, about 36.5 mole %, about 37 mole %, or about 37.5 mole % to any of about 38 mole %, about 38.5 mole %, about 39 mole %, about 39.5 mole %, or about 40 mole %, or any single value therein or any sub-range therein; and 2) aluminum oxide at a molar concentration ranging from any of about 60 mole %, about 60.5 mole %, about 61 mole %, about 61.5 mole %, or about 62 mole % to any of about 62.5 mole %, about 63 mole %, about 63.5 mole %, about 64 mole %, about 64.5 mole %, or about 65 mole %, or any single value therein or any sub-range therein.

In certain embodiments, it should be understood that any of the other chamber components, such as those listed above, may also include a plasma resistant protective coating and/or be made of any of the bulk compositions described herein.

In one embodiment, the processing chamber 100 includes a chamber body 102 and a lid 130 that enclose an interior volume 106. The chamber body 102 may be fabricated from aluminum, stainless steel or other suitable material. The chamber body 102 generally includes sidewalls 108 and a bottom 110. In certain embodiments, any of the lid 130, sidewalls 108 and/or bottom 110 may include a plasma resistant protective coating.

An outer liner 116 may be disposed adjacent the sidewalls 108 to protect the chamber body 102. The outer liner 116 may be fabricated and/or coated with a plasma resistant protective coating 136. In one embodiment, the outer liner 116 is fabricated from aluminum oxide.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The lid 130 may be supported on the sidewall 108 of the chamber body 102. The lid 130 may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through the nozzle 132. The lid 130 may be a ceramic such as Al₂O₃, Y₂O₃, YAG, SiO₂, AlN, SiN, SiC, Si—SiC, or a ceramic compound comprising Y₄Al₂O₉ and a solid-solution of Y₂O₃—ZrO₂. In one embodiment, lid 130 may be made of any of the bulk compositions described herein. The nozzle 132 may also be a ceramic, such as any of those ceramics mentioned for the lid. In one embodiment, nozzle 132 may be made of any of the bulk compositions described herein. The lid 130 and/or nozzle 132 may be coated with a plasma resistant protective coating 133, 134, respectively.

Examples of processing gases that may be used to process substrates in processing chamber 100 include halogen-containing gases and hydrogen-containing gases, such as C₂F₆, SF₆, SiCl₄, HBr, Br, NF₃, CF₄, CHF₃, CH₂F₃, F, NF₃, Cl₂, CCl₄, BCl₃, SiF₄, H₂, Cl₂, HCl, HF, among others, and other gases such as O₂, or N₂O. Examples of carrier gases include N₂, He, Ar, and other gases inert to process gases (e.g., non-reactive gases). A substrate support assembly 148 is disposed in the interior volume 106 of the processing chamber 100 below the lid 130. The substrate support assembly 148 holds the substrate 144 during processing. A ring 146 (e.g., a single ring) may cover a portion of the electrostatic chuck 150, and may protect the covered portion from exposure to plasma during processing. The ring 146 may be silicon or quartz in one embodiment.

An inner liner 118 may be coated on the periphery of the substrate support assembly 148. The inner liner 118 may be a halogen-containing gas resist material such as those discussed with reference to the outer liner 116. In one embodiment, the inner liner 118 may be fabricated from the same materials of the outer liner 116. Additionally, in certain embodiments, the inner liner 118 may be coated with a plasma resistant protective coating or may be made of any of the bulk compositions described herein.

In one embodiment, the substrate support assembly 148 includes a mounting plate 162 supporting a pedestal 152, and an electrostatic chuck 150. The electrostatic chuck 150 further includes a thermally conductive base 164 and an electrostatic puck 166 bonded to the thermally conductive base by a bond 138, which may be a silicone bond in one embodiment. The mounting plate 162 is coupled to the bottom 110 of the chamber body 102 and includes passages for routing utilities (e.g., fluids, power lines, sensor leads, etc.) to the thermally conductive base 164 and the electrostatic puck 166.

The thermally conductive base 164 and/or electrostatic puck 166 may include one or more optional embedded heating elements 176, embedded thermal isolators 174 and/or conduits 168, 170 to control a lateral temperature profile of the support assembly 148. The conduits 168, 170 may be fluidly coupled to a fluid source 172 that circulates a temperature regulating fluid through the conduits 168, 170. The embedded isolator 174 may be disposed between the conduits 168, 170 in one embodiment. The heater 176 is regulated by a heater power source 178. The conduits 168, 170 and heater 176 may be utilized to control the temperature of the thermally conductive base 164, heating and/or cooling the electrostatic puck 166 and a substrate (e.g., a wafer) 144 being processed. The temperature of the electrostatic puck 166 and the thermally conductive base 164 may be monitored using a plurality of temperature sensors 190, 192, which may be monitored using a controller 195.

The electrostatic puck 166 may further include multiple gas passages such as grooves, mesas and other surface features, that may be formed in an upper surface of the puck 166. The gas passages may be fluidly coupled to a source of a heat transfer (or backside) gas such as He via holes drilled in the puck 166. In operation, the backside gas may be provided at controlled pressure into the gas passages to enhance the heat transfer between the electrostatic puck 166 and the substrate 144.

The electrostatic puck 166 includes at least one clamping electrode 180 controlled by a chucking power source 182. The electrode 180 (or other electrode disposed in the puck 166 or base 164) may further be coupled to one or more RF power sources 184, 186 through a matching circuit 188 for maintaining a plasma formed from process and/or other gases within the processing chamber 100. The sources 184, 186 are generally capable of producing RF signal having a frequency from about 50 kHz to about 3 GHz and a power of up to about 10,000 Watts. In certain embodiments, the bulk compositions described herein and/or the coating compositions described herein have a high energy plasma resistance when exposed, for example, for a power of up to about 10,000 Watts.

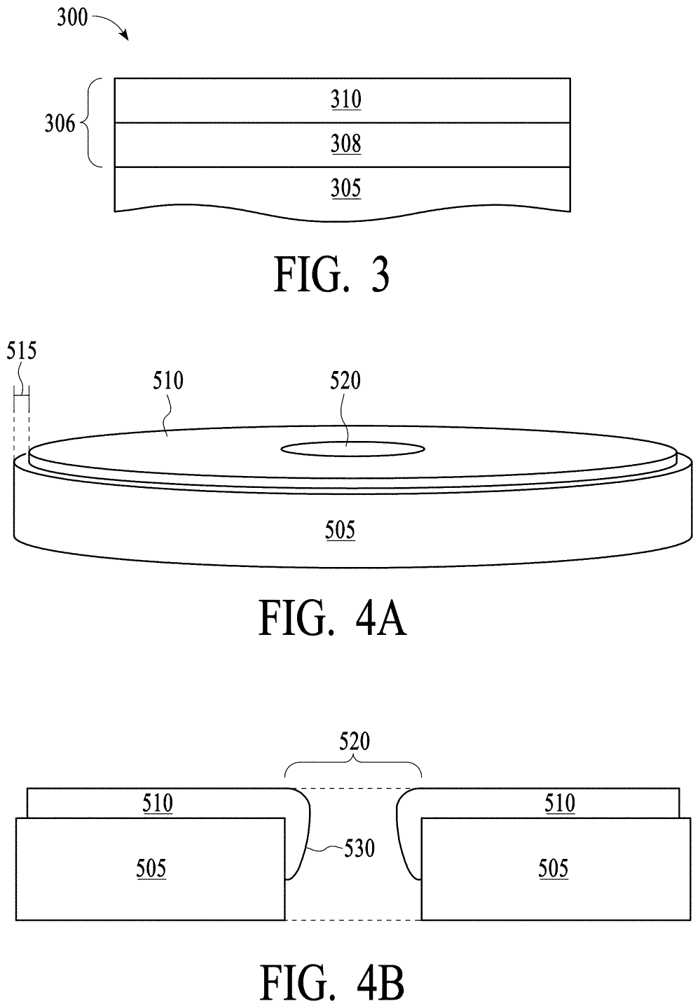

FIG. 3 illustrates a cross sectional side view of an article that may be covered by one or more plasma resistant protective coatings (e.g., chamber components such as lids and/or doors and/or liners and/or nozzles).

Referring to FIG. 3, a body 305 of the chamber component 300 includes a coating stack 306 having a first plasma resistant protective coating 308 and a second plasma resistant protective coating 310. Alternatively, the article 300 may include only a single plasma resistant protective coating 308 on the body 305. In certain embodiments, body 305 is made of any one of the bulk compositions described herein. In embodiments where body 305 is made of any one of the bulk compositions described herein it may or may not be further coated with one or more plasma resistant protective coatings 308, 310.

In certain embodiments, various chamber component in a processing chamber may be coated with the plasma resistant protective coating described herein and/or be made of any one of the bulk compositions described herein, including but not limited to, a lid, a lid liner, a nozzle, a substrate support assembly, a gas distribution plate, a showerhead, an electrostatic chuck, a shadow frame, a substrate holding frame, a processing kit ring, a single ring, a chamber wall, a base, a liner kit, a shield, a plasma screen, a flow equalizer, a cooling base, a chamber viewport, or a chamber liner.

In one embodiment, the plasma resistant protective coatings 308, 310 have a thickness of up to about 300 μm. In a further embodiment, the plasma resistant protective coatings have a thickness of below about 20 microns, such as a thickness between about 0.5 microns to about 12 microns, a thickness of between about 2 microns to about 12 microns, a thickness of about 2 microns to about 10 microns, a thickness of about 3 microns to about 7 microns, a thickness of about 4 microns to about 6 microns, or any sub-range therein or single thickness value therein. A total thickness of the plasma resistant protective coating stack in one embodiment is 300 μm or less.

In certain embodiments, the plasma resistant protective coating provides full coating coverage to the underlying surface and is uniform in thickness. The uniform thickness of the coating across different sections of the coating may be evidenced by a variation in thickness that is about 15% or less, about 10% or less, or about 5% or less in one section of the coating as compared to another section of the coating (or based on a standard deviation derived from a plurality of thicknesses from different sections of the coating).

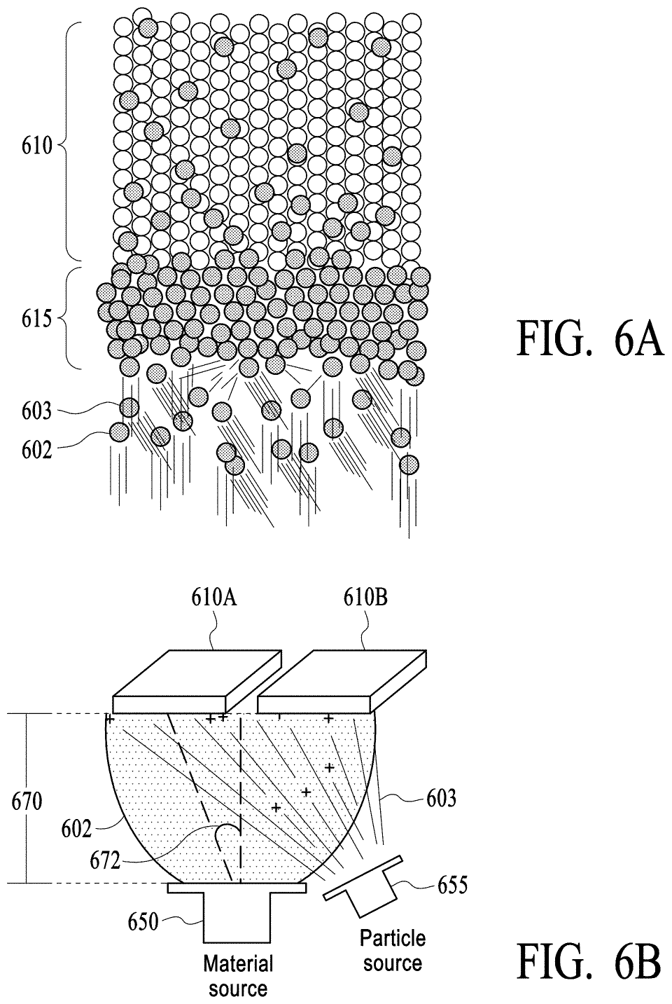

In certain embodiments, the plasma resistant protective coating(s) (e.g., 308 and/or 310) are deposited on body 305 of article 300 using an electron beam ion assisted deposition (EB-IAD) process, as described in further detail with respect to FIGS. 6A-6B. The EB-IAD deposited plasma resistant protective coating(s) may have a relatively low film stress (e.g., as compared to a film stress caused by plasma spraying or sputtering). In certain embodiments, the relatively low film stress may cause the lower surface of the body 305 to be very flat, with a curvature of less than about 50 microns over the entire body for a body with a 12 inch diameter. In certain embodiments, the curvature measure on 12″ wafer indirectly indicates low stress of low curvature. In certain embodiments, the lid flexural strength of a lid coated with an EB-IAD deposited plasma resistant protective coating is about 412 MPa. In certain embodiments, the lid flexural strength may be tested with bend flexural testing.

In certain embodiments, the plasma resistant protective coatings described herein do not exhibit any gaps, pin holes or uncoated areas. The EB-IAD deposited plasma resistant protective coating(s) has essentially 0% porosity (i.e., no porosity) in embodiments, as analyzed via cross-section morphology. This low porosity may enable the chamber component to provide an effective vacuum seal during processing. Hermeticity measures the sealing capacity that can be achieved using the plasma resistant protective coating. A He leak rate of around less than 3E-9 (cm³/s), less than 2E-9 (cm³/s), or less than 1E-9 (cm³/s) can be achieved using a 5 micrometer thick EB-IAD deposited plasma resistant protective coating, according to an embodiment. In comparison, a He leak rate of around 1E-6 cubic centimeters per second (cm³/s) can be achieved using alumina. Lower He leak rates indicate an improved seal. The hermeticity may be measured by placing a coated coupon over O-ring of Helium test stand and pumping down the pressure until the gauge <E-9 torr/s (or <1.3E-9 cm³/s), applying helium around the O-ring using a flow rate of helium of about 30 sccm by slowly moving the helium source around the O-ring and measuring the leak rate.

In certain embodiments, the EB-IAD deposited plasma resistant protective coating has a dense structure, which can have performance benefits for application on a chamber lid for example. Additionally, the EB-IAD deposited plasma resistant protective coating may have a low crack density and a high adhesion to the body 305, which can be beneficial for reducing cracks in the coating (both vertical and horizontal), delamination of the coating, yttrium-based particle generation by the coating, and yttrium-based particle defects on a wafer. In certain embodiments, adhesion strength of a 5 micrometer thick EB-IAD deposited plasma resistant protective coating to an aluminum substrate may be greater than about 25 MPa, greater than about 26 MPa, greater than about 27 MPa, or greater than about 28 MPa. In certain embodiments, the adhesion strength may be measured via tensile testing per ASTM 633C or JIS H8666.

In certain embodiments, the roughness of the plasma resistant protective coating may be approximately unchanged from the starting roughness of the underlying substrate that is being coated. For instance, in certain embodiments, the starting roughness of the substrate may be about 8-16 micro-inches and the roughness of the coating may be approximately unchanged. In certain embodiments, the starting roughness of the underlying substrate may be lower than about 8 micro-inches, e.g. about 4 to about 8 micro-inches, and the roughness of the plasma resistant protective coating may be approximately unchanged. The plasma resistant protective coating may have a surface roughness of about 8 micro-inches or below or about 6 micro-inches or below.

In certain embodiments, the plasma resistant protective coating has a high hardness that may resist wear during plasma processing. A 5 micrometer thick, EB-IAD deposited plasma resistant protective coating, according to an embodiment, has a hardness of about ≥7 GPa, e.g., about 8 GPa. The hardness of the coating is determined by nano-indentation in accordance with ASTM E2546-07.

A 5 micrometer thick, EB-IAD deposited plasma resistant protective coating, according to an embodiment, has a breakdown voltage of greater than 2,500 V/mil coating. The breakdown voltage is determined in accordance with JIS C 2110.

The plasma resistant protective coatings described herein may have trace metals, such as one or more of: Ca, Cr, Cu, Fe, Mg, Mn, Ni, K, Mo, Na, Ti, Zn. Trace metal levels are determined using Laser Ablation Inductively Coupled Plasma Mass Spectrometry (LA ICPMS) at a depth of 2 μm. In certain embodiments, plasma resistant protective coatings described herein have a purity of about 99.5% or more, about 99.6% or more, about 99.7% or more, about 99.8% or more, or about 99.9% or more, based on atom % or based on wt % of the plasma resistant protective coating.

Chamber components having EB-IAD plasma resistant protective coatings may be used in applications that apply a wide range of temperatures. For example, plasma resistant protective coatings described herein may be stable at operating temperatures ranging from about 80° C. to about 120° C.

Note that the composition of the plasma resistant protective coating described herein (whether deposited by EB-IAD, PVD, plasma spray, or any other deposition method contemplated herein) may be modified such that the material properties and characteristics identified above may vary by up to 10% in some embodiments, or up to 30% in other embodiments. Accordingly, in certain embodiments, the described values for the plasma resistant protective coating properties should be understood as example achievable values. In certain embodiments, the plasma resistant protective coatings described herein should not be interpreted as being limited to the provided values.

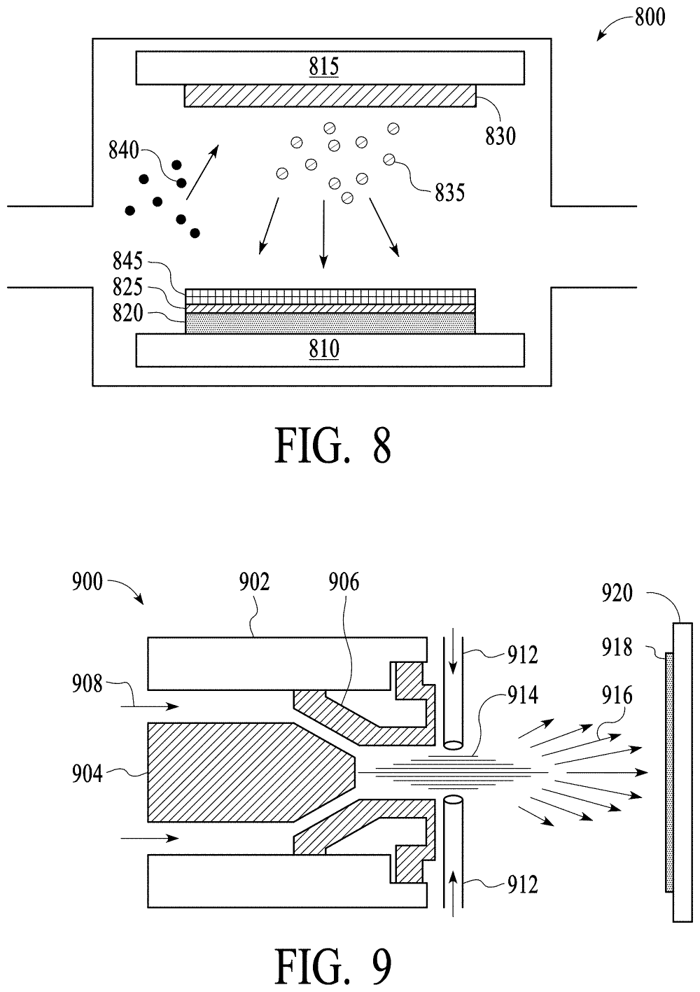

In certain embodiments, plasma resistant protective coating(s) (e.g., 308 and/or 310) are deposited on body 305 of article 300 using physical vapor deposition (PVD) as described in further detail with respect to FIG. 8, plasma spray as described in further detail with respect to FIG. 9, an ion assisted deposition (IAD) process without an e-beam, or any other suitable deposition process.

As previously mentioned, various chamber components in a processing chamber may be coated with the plasma resistant protective coating described herein (deposited by IAD, plasma spray or PVD) and/or be made of any one of the bulk compositions described herein. In one embodiment, the chamber components that are made of the bulk compositions described herein and/or are coated with the plasma resistant protective coatings described herein include one or more of a lid (e.g., 130), a nozzle (e.g., 132), and/or a liner (e.g., 116 and/or 118). In one embodiment, the chamber component is a lid which may be made of the bulk composition described herein and/or coated with a plasma resistant protective coating described herein. In one embodiment, the chamber component is a nozzle which may be made of the bulk composition described herein and/or coated with a plasma resistant protective coating described herein. In one embodiment, the chamber component is a liner which may be made of the bulk composition described herein and/or coated with a plasma resistant protective coating described herein. In one embodiment, the chamber component is a kit including two or more of a lid, a nozzle, and a liner, each of which may be made of the bulk composition described herein and/or coated with a plasma resistant protective coating described herein.

FIG. 4A illustrates a perspective view of a chamber lid 505 (similar to chamber lid 130 in FIG. 1) having a plasma resistant protective coating 510, in accordance with one exemplary embodiment. FIG. 4B illustrates a cross-sectional side view of a chamber lid 505 having a plasma resistant protective coating 510 (similar to coating 133 in FIG. 1), in accordance with one exemplary embodiment. The chamber lid 505 includes a hole 520, which may be at a center of the lid or elsewhere on the lid. The lid 505 may also have a lip 515 that will be in contact with walls of a chamber while the lid is closed. In one embodiment, the plasma resistant protective coating 510 does not cover the lip 515. To ensure that the plasma resistant protective coating does not cover the lip 515, a hard or soft mask may be used that covers the lip 515 during deposition. The mask may then be removed after deposition. Alternatively, the protective layer 510 may coat the entire surface of the lid. Accordingly, the protective layer 510 may rest on side walls of a chamber during processing.

As shown in FIG. 4B, the plasma resistant protective coating 510 may have a sidewall portion 530 that coats an interior of the hole 520. The sidewall portion 530 of the protective layer 510 may be thicker near a surface of the lid 505, and may gradually become thinner deeper into the hole 520. The sidewall portion 530 may not coat an entirety of the sidewalls of the hole 520 in such embodiments.

FIG. 6A depicts a deposition mechanism applicable to a variety of deposition techniques utilizing energetic particles such as ion assisted deposition (IAD). Exemplary IAD methods include deposition processes which incorporate ion bombardment, such as evaporation (e.g., activated reactive evaporation (ARE)) and sputtering in the presence of ion bombardment to form plasma resistant protective coatings as described herein. One particular type of IAD performed in embodiments is electron beam IAD (e-beam IAD). Any of the IAD methods may be performed in the presence of a reactive gas species, such as O₂, N₂, halogens (e.g., fluorine), Argon, etc. Reactive species may burn off surface organic contaminants prior to and/or during deposition. Additionally, the IAD deposition process for ceramic target deposition vs. the metal target deposition can be controlled by partial pressure of 02 ions in embodiments. Alternatively, a ceramic target can be used with no oxygen or reduced oxygen. In certain embodiments, the IAD deposition is performed in the presence of oxygen and/or argon. In certain embodiments, the IAD deposition is performed in the presence of fluorine so as to deposit the coating with fluorine incorporated into the coating. Coatings with fluorine incorporated therein are believed to be less likely to interact with wafer processes that include similar environments (e.g., processing with a fluorine environment).

As shown, the plasma resistant protective coating 615 (similar to coating 133, 134, and 136 in FIGS. 1, 308 and/or 310 in FIG. 3, 510 in FIGS. 4A and 4B) is formed on an article 610 or on multiple articles 610A, 610B (such as any of the chamber components described before including a lid and/or a nozzle and/or a liner) by an accumulation of deposition materials 602 in the presence of energetic particles 603 such as ions. The deposition materials 602 may include atoms, ions, radicals, and so on. The energetic particles 603 may impinge and compact the plasma resistant protective coating 615 as it is formed.

In one embodiment, EB-IAD is utilized to form the plasma resistant protective coating 615. FIG. 6B depicts a schematic of an IAD deposition apparatus. As shown, a material source 650 provides a flux of deposition materials 602 while an energetic particle source 655 provides a flux of the energetic particles 603, both of which impinge upon the article 610, 610A, 610B throughout the IAD process. The energetic particle source 655 may be oxygen or other ion source. The energetic particle source 655 may also provide other types of energetic particles such as radicals, neutrons, atoms, and nano-sized particles which come from particle generation sources (e.g., from plasma, reactive gases or from the material source that provide the deposition materials).

The material source (e.g., a target body or a plug material) 650 used to provide the deposition materials 602 may be a bulk sintered ceramic corresponding to the same ceramic that the plasma resistant protective coating 615 is to be composed of The material source may be or include a bulk sintered ceramic compound body, such as bulk sintered YAG, a bulk sintered Y₂O₃ and/or bulk sintered Al₂O₃, and/or other mentioned ceramics. In some embodiments, multiple material sources are used, such as a first material source of a bulk sintered Y₂O₃ target and a second material source of a bulk sintered Al₂O₃ target. Other target materials may also be used, such as powders, calcined powders, preformed material (e.g., formed by green body pressing or hot pressing), or a machined body (e.g., fused material). All of the different types of material sources 650 are melted into molten material sources during deposition. However, different types of starting material take different amounts of time to melt. Fused materials and/or machined bodies may melt the quickest. Preformed material melts slower than fused materials, calcined powders melt slower than preformed materials, and standard powders melt more slowly than calcined powders.

In some embodiments, the material source is a metallic material (e.g., a mixture of Y and Al, or two different targets, one of Y and one of Al). Such a material source may be bombarded by oxygen ions to form an oxide coating. Additionally, or alternatively, an oxygen gas (and/or an oxygen plasma) may be flowed into a deposition chamber during the IAD process to cause the sputtered or evaporated metals of Y and Al to interact with oxygen and form an oxide coating.

IAD may utilize one or more plasmas or beams (e.g., electron beams) to provide the material and energetic ion sources. Reactive species may also be provided during deposition of the plasma resistant coating. In one embodiment, the energetic particles 603 include at least one of non-reactive species (e.g., Ar) or reactive species (e.g., O). In further embodiments, reactive species such as CO and halogens (Cl, F, Br, etc.) may also be introduced during the formation of a plasma resistant protective coating to further increase the tendency to selectively remove deposited material most weakly bonded to the plasma resistant protective coating 615.

With IAD processes, the energetic particles 603 may be controlled by the energetic ion (or other particle) source 655 independently of other deposition parameters. According to the energy (e.g., velocity), density and incident angle of the energetic ion flux, composition, structure, crystalline orientation, grain size, and amorphous nature of the plasma resistant protective coating may be manipulated.

Additional parameters that may be adjusted are a temperature of the article during deposition as well as the duration of the deposition. In one embodiment, an IAD deposition chamber (and the chamber lid) is heated to a starting temperature of 70° C. or higher prior to deposition. In one embodiment, the starting temperature is 50° C. to 250° C. In one embodiment, the starting temperature is 50° C. to 100° C. The temperature of the chamber and of the lid may then be maintained at the starting temperature during deposition. In one embodiment, the IAD chamber includes heat lamps which perform the heating. In an alternative embodiment, the IAD chamber and lid are not heated. If the chamber is not heated, it will naturally increase in temperature to about 70° C. as a result of the IAD process. A higher temperature during deposition may increase a density of the plasma resistant protective coating but may also increase a mechanical stress of the plasma resistant protective coating. Active cooling can be added to the chamber to maintain a low temperature during coating. The low temperature may be maintained at any temperature at or below 70° C. down to 0° C. in one embodiment.

Additional parameters that may be adjusted are working distance 670 and angle of incidence 672. The working distance 670 is the distance between the material source 650 and the article 610A, 610B. In one embodiment, the working distance is 0.2 to 2.0 meters, with a working distance of 1.0 meters in one particular embodiment. Decreasing the working distance increases a deposition rate and increases an effectiveness of the ion energy. However, decreasing the working distance below a particular point may reduce a uniformity of the protective layer. The angle of incidence is an angle at which the deposition materials 602 strike the articles 610A, 610B. In one embodiment the angle of incidence is 10-90 degrees.

IAD coatings can be applied over a wide range of surface conditions with roughness from about 0.1 micro-inches (pin) to about 180 μm. However, smoother surface facilitates uniform coating coverage. The coating thickness can be up to about 300 microns (μm). In production, coating thickness on components can be assessed by purposely adding a rare earth oxide based colored agent such Nd₂O₃, Sm₂O₃, Er₂O₃, etc. at the bottom of a coating layer stack. The thickness can also be accurately measured using ellipsometry.

In embodiments described herein, IAD coatings are amorphous. Amorphous coatings are more conformal and reduce lattice mismatch induced epitaxial cracks as compared to crystalline coatings. In one embodiments, the plasma resistant protective coating described herein is 100% amorphous and has zero crystallinity. In certain embodiments, the plasma resistant protective coating described herein is conformal and has a low film stress.

Co-deposition of multiple targets using multiple electron beam (e-beam) guns can be achieved to create thicker coatings as well as layered architectures. For example, two targets having the same material type may be used at the same time. Each target may be bombarded by a different electron beam gun. This may increase a deposition rate and a thickness of the protective layer. In another example, two targets may be different ceramic materials. For example, one target of Al or Al₂O₃ and another target of Y or Y₂O₃ may be used. A first electron beam gun may bombard a first target to deposit a first protective layer, and a second electron beam gun may subsequently bombard the second target to form a second protective layer having a different material composition than the first protective layer.

In an embodiment, a single target material (also referred to as plug material) and a single electron beam gun may be used to arrive at the plasma resistant protective coating described herein.

In one embodiment, multiple chamber components (e.g., multiple lids or multiple liners or multiple nozzles) are processed in parallel in an IAD chamber. Each chamber component may be supported by a different fixture. Alternatively, a single fixture may be configured to hold multiple chamber components. The fixtures may move the supported chamber components during deposition.

In one embodiment, a fixture to hold a chamber component can be designed out of metal components such as cold rolled steel or ceramics such as Al₂O₃, Y₂O₃, etc. The fixture may be used to support the chamber component above or below the material source and electron beam gun. The fixture can have a chucking ability to chuck the chamber component for safer and easier handling as well as during coating. Also, the fixture can have a feature to orient or align the chamber component. In one embodiment, the fixture can be repositioned and/or rotated about one or more axes to change an orientation of the supported chamber component to the source material. The fixture may also be repositioned to change a working distance and/or angle of incidence before and/or during deposition. The fixture can have cooling or heating channels to control the chamber component's temperature during coating. The ability or reposition and rotate the chamber component may enable maximum coating coverage of 3D surfaces such as holes since IAD is a line of sight process.

In certain embodiments, the IAD deposited plasma resistant protective coating described herein provides a greater chemical resistance to corrosive chemistry (e.g., hydrogen based chemistry, halogen based chemistry, or a mixture thereof) as compared to other yttrium based coating compositions and/or as compared to other coatings that may have the same chemical composition but different mechanical properties (e.g., density, porosity, hardness, breakdown voltage, roughness, hermeticity, adhesion strength, crystallinity/amorphous nature, and so on) and/or chemical properties (e.g., chemical resistivity). For instance, in one embodiment, the IAD deposited plasma resistant protective coating has a chemical composition that corresponds to the chemical composition of YAG or near the chemical composition of YAG (in terms of the amount of aluminum, yttrium, and oxygen) that provide for enhanced chemical resistance at aggressive chemical environment (e.g., aggressive halogen and/or hydrogen acidic environments) and/or enhanced plasma resistance as compared to other yttrium based coatings and/or as compared to other YAG coatings prepared and/or deposited differently from the instant disclosure.

The enhanced chemical resistance of IAD deposited plasma resistant protective coating described herein as compared to other yttrium based coatings is illustrated in FIGS. 7A1, 7A2, 7B1, 7B2, 7C1, 7C2, 7D1, and 7D2. FIGS. 7A1 and 7A2 depict a yttria (Y₂O₃) IAD deposited coating prior to exposure (FIG. 7A1) and after exposure (FIG. 7A2) to an aggressive acid soak for 60 minutes in a concentrated halogen based acid (e.g., HCl, HF, HBr). As per FIG. 7A2, the yttria IAD deposited coating was gone after the accelerated chemical resistance test (i.e., FIG. 7A2 depicts that 100% of the coating was attacked). FIGS. 7B1 and 7B2 depict an IAD deposited coating consisting of a ceramic compound comprising Y₄Al₂O₉ and a solid-solution of Y₂O₃—ZrO₂ prior to exposure (FIG. 7B1) and after exposure (FIG. 7B2) to an aggressive acid soak for 60 minutes in a concentrated halogen based acid (e.g., HCl, HF, HBr). As per FIG. 7B2, the IAD deposited coating consisting of a ceramic compound comprising Y₄Al₂O₉ and a solid-solution of Y₂O₃—ZrO₂ was almost gone after the accelerated chemical resistance test (i.e., FIG. 7B2 depicts that 70% of the coating was attacked). FIGS. 7C1 and 7C2 depict an IAD deposited coating consisting of a Y₂O₃—ZrO₂ solid solution prior to exposure (FIG. 7C1) and after exposure (FIG. 7C2) to an aggressive acid soak for 60 minutes in a concentrated halogen based acid (e.g., HCl, HF, HBr). As per FIG. 7C2, the IAD deposited coating consisting of a Y₂O₃—ZrO₂ solid solution was gone after the accelerated chemical resistance test (i.e., FIG. 7C2 depicts that 100% of the coating was attacked).

FIGS. 7D1 and 7D2 depict an IAD deposited single phase amorphous YAG coating (i.e., an amorphous single phase blend of yttria and alumina having a composition of yttria and alumina that corresponds to YAG on the alumina-yttria phase diagram depicted in FIG. 2), according to an embodiment, prior to exposure (FIG. 7D1) and after exposure (FIG. 7D2) to an aggressive acid soak for 60 minutes in a concentrated halogen based acid (e.g., HCl, HF, HBr). No damage was observed in the IAD deposited single phase amorphous YAG coating after the accelerated chemical resistance test (i.e., FIG. 7D2 depicts that 0% of the coating was attacked).

FIGS. 7A1 through 7D2 illustrate that plasma resistant protective coatings deposited by IAD, according to embodiments described herein, exhibit improved chemical resistance to harsh chemical environments (e.g., harsh acidic environments as well as halogen and/or hydrogen based environments) as compared to other yttrium based IAD deposited coatings. Such chemical resistance also contributes to a reduced number of yttrium based particles over extended processing duration and correspondingly to reduced wafer defectivity.

Without being construed as limiting, it can be appreciated from FIGS. 7A1 to 7D2 that, in certain embodiments, with increasing aluminum/alumina concentration in the IAD deposited plasma resistant coating composition, the chemical resistance of the coating (as determined based on an acid stress test) improved.

Plasma resistant protective coatings described herein may be deposited using a physical vapor deposition (PVD) process. PVD processes may be used to deposit thin films with thicknesses ranging from a few nanometers to several micrometers. The various PVD processes share three fundamental features in common: (1) evaporating the material from a solid source with the assistance of high temperature or gaseous plasma; (2) transporting the vaporized material in vacuum to the article's surface; and (3) condensing the vaporized material onto the article to generate a thin film layer. An illustrative PVD reactor is depicted in FIG. 8.

FIG. 8 depicts a deposition mechanism applicable to a variety of PVD techniques and reactors. PVD reactor chamber 800 may comprise a plate 810 adjacent to the article 820 and a plate 815 adjacent to the target 830. In certain embodiments, a plurality of targets (e.g., two targets) may be used. Air may be removed from reactor chamber 800, creating a vacuum. Then gas (such as argon gas or oxygen gas) may be introduced into the reactor chamber, voltage may be applied to the plates, and a plasma comprising electrons and positive ions (such as argon ions or oxygen ions) 840 may be generated. Ions 840 may be positive ions and may be attracted to negatively charged plate 815 where they may hit one or more target(s) 830 and release atoms 835 from the target. Released atoms 835 may get transported and deposited as a coating 825 onto article 820. The coating may have a single layer architecture or may include a multi-layer architecture (e.g., layers 825 and 845).

Article 820 in FIG. 8 may represent various semiconductor process chamber components including but not limited to substrate support assembly, an electrostatic chuck (ESC), a ring (e.g., a process kit ring or single ring), a chamber wall, a base, a gas distribution plate, gas lines, a showerhead, a nozzle, a lid, a liner, a liner kit, a shield, a plasma screen, a flow equalizer, a cooling base, a chamber viewport, a chamber lid, and so on.

Coating 825 (and optionally 845) in FIG. 8 may represent any of the plasma resistant protective coatings described herein. Coating 825 (and optionally 845) can have the same composition of aluminum/alumina, yttria/yttrium, and oxygen as the coatings previously described. Similarly, plasma resistant protective coating 825 (and optionally 845) can have any of the properties described hereinbefore, such as, without limitations, percent amorphous, porosity, density, adhesion strength, roughness, chemical resistance, physical resistance, hardness, purity, breakdown voltage, flexural strength, hermeticity, stability and so on.

Furthermore, plasma resistant protective coating 825 (and optionally 845) can exhibit reduced defectivity (as estimated based on yttrium-based particle defects per wafer) upon exposure to aggressive chemical environment and/or to aggressive plasma environment over extended processing duration.

Plasma resistant protective coatings described herein may be deposited using a plasma spray process, an example of which is depicted in FIG. 9. FIG. 9 depicts a sectional view of a plasma spray device 900 according to an embodiment. The plasma spray device 900 is a type of thermal spray system that is used to perform “slurry plasma spray” (“SPS”) deposition of ceramic materials. While the description below will be described with respect to the SPS technique, other standard plasma spray techniques that use a dry powder mixture may also be utilized to deposit the coatings described herein.

SPS deposition utilizes a solution-based distribution of particles (a slurry) to deposit a ceramic coating on a substrate. The SPS may be performed by spraying the slurry using atmospheric pressure plasma spray (APPS), high velocity oxy-fuel (HVOF), warm spraying, vacuum plasma spraying (VPS), and low pressure plasma spraying (LPPS).

The plasma spray device 900 may include a casing 902 that encases a nozzle anode 906 and a cathode 904. The casing 902 permits gas flow 908 through the plasma spray device 900 and between the nozzle anode 906 and the cathode 904. An external power source may be used to apply a voltage potential between the nozzle anode 906 and the cathode 904. The voltage potential produces an arc between the nozzle anode 906 and the cathode 904 that ignites the gas flow 908 to produce a plasma gas. The ignited plasma gas flow 908 produces a high-velocity plasma plume 914 that is directed out of the nozzle anode 906 and toward a substrate 920.

The plasma spray device 900 may be located in a chamber or atmospheric booth. In some embodiments, the gas flow 908 may be a gas or gas mixture including, but not limited to argon, oxygen, nitrogen, hydrogen, helium, and combinations thereof. In certain embodiments, other gases, such as fluorine, may be introduced to incorporate some fluorine into the coating so that it is more resistant to wear in a fluorine processing environment.

The plasma spray device 900 may be equipped with one or more fluid lines 912 to deliver a slurry into the plasma plume 914. In some embodiments, several fluid lines 912 may be arranged on one side or symmetrically around the plasma plume 914. In some embodiments, the fluid lines 912 may be arranged in a perpendicular fashion to the plasma plume 914 direction, as depicted in FIG. 9. In other embodiments, the fluid lines 912 may be adjusted to deliver the slurry into the plasma plume at a different angle (e.g., 45°), or may be located at least partially inside of the casing 902 to internally inject the slurry into the plasma plume 914. In some embodiments, each fluid line 912 may provide a different slurry, which may be utilized to vary a composition of a resulting coating across the substrate 920.

A slurry feeder system may be utilized to deliver the slurry to the fluid lines 912. In some embodiments, the slurry feeder system includes a flow controller that maintains a constant flow rate during coating. The fluid lines 912 may be cleaned before and after the coating process using, for example, de-ionized water. In some embodiments, a slurry container, which contains the slurry fed to the plasma spray device 900, is mechanically agitated during the course of the coating process keep the slurry uniform and prevent settling.

Alternatively, in standard powder based plasma spray techniques, a powder delivery system, that includes one or more powder containers filled with one or more different powders, may be used to deliver powder into the plasma plume 914 (not shown).

The plasma plume 914 can reach very high temperatures (e.g., between about 3000° C. to about 10000° C.). The intense temperature experienced by the slurry (or slurries) when injected into the plasma plume 914 may cause the slurry solvent to evaporate quickly and may melt the ceramic particles, generating a particle stream 916 that is propelled toward the substrate 920. In a standard powder based plasma spray technique, the intense temperature of the plasma plume 914 also melts the powder delivered thereto and propels the molten particles toward the substrate 920. Upon impact with the substrate 920, the molten particles may flatten and rapidly solidify on the substrate, forming a ceramic coating 918. The solvent may be completely evaporated prior to the ceramic particles reaching the substrate 920.

Plasma resistant protective coatings deposited using plasma spray deposition may, in certain embodiments, have a greater porosity than that of coatings deposited by e-beam IAD. For instance, in certain embodiments, plasma spray deposited plasma resistant protective coatings may have a porosity of up to about 10%, up to about 8%, up to about 6%, up to about 4%, up to about 3%, up to about 2%, up to about 1%, or up to about 0.5%. In certain embodiments, the porosity is measured via a 1000× Scanning Electron Microscope (SEM) image with software to calculate the percent area of porosity.

The parameters that can affect the thickness, density, and roughness of the ceramic coating include the slurry conditions, the particle size distribution, the slurry feed rate, the plasma gas composition, the gas flow rate, the energy input, the spray distance, and substrate cooling.

Article 920 in FIG. 9 may represent various semiconductor process chamber components including but not limited to substrate support assembly, an electrostatic chuck (ESC), a ring (e.g., a process kit ring or single ring), a chamber wall, a base, a gas distribution plate, gas lines, a showerhead, a nozzle, a lid, a liner, a liner kit, a shield, a plasma screen, a flow equalizer, a cooling base, a chamber viewport, a chamber lid, and so on.

Coating 918 in FIG. 9 may represent any of the plasma resistant protective coatings described herein. Coating 918 can have the same composition of aluminum/alumina, yttria/yttrium, and oxygen as the coatings previously described. Similarly, plasma resistant protective coating 918 can have any of the properties described hereinbefore, such as, without limitations, percent amorphous (e.g., greater than any of about 80%, about 85%, about 90%, about 95%, or about 98% amorphous), porosity (e.g., lower than any of about 2%, about 1.5%, about 1%, about 0.5%, or about 0.1%), density, adhesion strength (e.g., greater than any of about 18 MPa, about 20 MPa, about 23 MPa, about 25 MPa, about 28 MPa, or about 30 MPa), chemical resistance, physical resistance, hardness (e.g., greater than any of about 6 GPa, about 7 GPa, about 8 GPa, about 9 GPa, or about 10 GPa), purity, breakdown voltage (greater than any of about 800 V/Mil, about 1000 V/Mil, about 1250 V/Mil, about 1500 V/Mil, or about 2000 V/Mil), roughness, flexural strength, hermeticity, stability and so on. Furthermore, Coating 918 can exhibit reduced defectivity (as estimated based on yttrium-based particle defects per wafer) upon exposure to aggressive chemical environment and/or to aggressive plasma environment over extended processing duration.

In certain embodiments, a plasma resistant protective coating deposited by plasma spray, as described herein, provides a greater chemical resistance to corrosive chemistry (e.g., hydrogen based chemistry, halogen based chemistry, or a mixture thereof) as compared to other yttrium based coating compositions and/or as compared to other coatings that may have the same chemical composition but different mechanical properties (e.g., density, porosity, hardness, breakdown voltage, roughness, hermeticity, adhesion strength, crystallinity/amorphous nature, and so on) and/or chemical properties (e.g., chemical resistivity). For instance, in one embodiment, the plasma spray deposited plasma resistant protective coating has a chemical composition that corresponds to the chemical composition of YAG or near the chemical composition of YAG (in terms of the amount of aluminum, yttrium, and oxygen) that provides for enhanced chemical resistance at aggressive chemical environment (e.g., aggressive halogen and/or hydrogen acidic environments) and/or enhanced plasma resistance as compared to other yttrium based coatings and/or as compared to other YAG coatings prepared and/or deposited differently from the instant disclosure.

The enhanced chemical resistance of plasma sprayed plasma resistant protective coatings described herein as compared to other yttrium based coating compositions deposited by plasma spray is illustrated in FIGS. 10A1,10A2, 10B1, 10B2, 10C1, 10C2, 10D1, and 10D2. FIGS. 10A1 and 10A2 depict a yttria (Y₂O₃) coating deposited by plasma spray prior to exposure (FIG. 10A1) and after exposure (FIG. 10A2) to an aggressive acid soak for 60 minutes in a concentrated halogen based acid (e.g., HCl, HF, HBr). As per FIG. 10A2, the plasma sprayed yttria coating exhibited heavy damage (in more than 25% of the examined coating area) after the accelerated chemical resistance test (e.g., FIG. 10A2 illustrates that about 50% of the examined coating area was attacked). FIGS. 10B1 and 10B2 depict a coating deposited by plasma spray consisting of a ceramic compound comprising Y₄Al₂O₉ and a solid-solution of Y₂O₃—ZrO₂ prior to exposure (FIG. 10B1) and after exposure (FIG. 10B2) to an aggressive acid soak for 60 minutes in a concentrated halogen based acid (e.g., HCl, HF, HBr). As per FIG. 10B2, the plasma sprayed coating consisting of a ceramic compound comprising Y₄Al₂O₉ and a solid-solution of Y₂O₃—ZrO₂ exhibited localized, medium damage (in 15% of the examined coating area) after the accelerated chemical resistance test. FIGS. 10C1 and 10C2 depict a coating consisting of a Y₂O₃—ZrO₂ solid solution deposited by plasma spray prior to exposure (FIG. 10C1) and after exposure (FIG. 10C2) to an aggressive acid soak for 60 minutes in a concentrated halogen based acid (e.g., HCl, HF, HBr). As per FIG. 10C2, the plasma sprayed coating consisting of the Y₂O₃—ZrO₂ solid solution exhibited localized, medium to heavy damage (in 30% of the examined coating area) after the accelerated chemical resistance test.

FIGS. 10D1 and 10D2 depict a plasma sprayed substantially amorphous YAG coating (i.e., an at least 90% amorphous blend of yttria and alumina having a composition of yttria and alumina that corresponds to YAG on the alumina-yttria phase diagram depicted in FIG. 2), according to an embodiment, prior to exposure (FIG. 10D1) and after exposure (FIG. 10D2) to an aggressive acid soak for 60 minutes in a concentrated halogen based acid (e.g., HCl, HF, HBr). Localized, minor damage and substantially no damage (in about 0%-3% of the examined coating area) was observed in the plasma sprayed substantially amorphous YAG coating after the accelerated chemical resistance test.

FIGS. 10A1 through 10D2 illustrate that plasma resistant protective coatings deposited by plasma spray, according to embodiments described herein, exhibit improved chemical resistance to harsh chemical environments (e.g., harsh acidic environments as well as halogen and/or hydrogen based environments) as compared to other yttrium based plasma sprayed coatings. Such chemical resistance also contributes to a reduced number of yttrium based particles over extended processing duration and correspondingly to reduced wafer defectivity.

Without being construed as limiting, it can be appreciated from FIGS. 10A1 to 10D2 that, in certain embodiments, with increasing aluminum/alumina concentration in the plasma sprayed coating composition, the chemical resistance of the coating (as determined based on an acid stress test) improved.

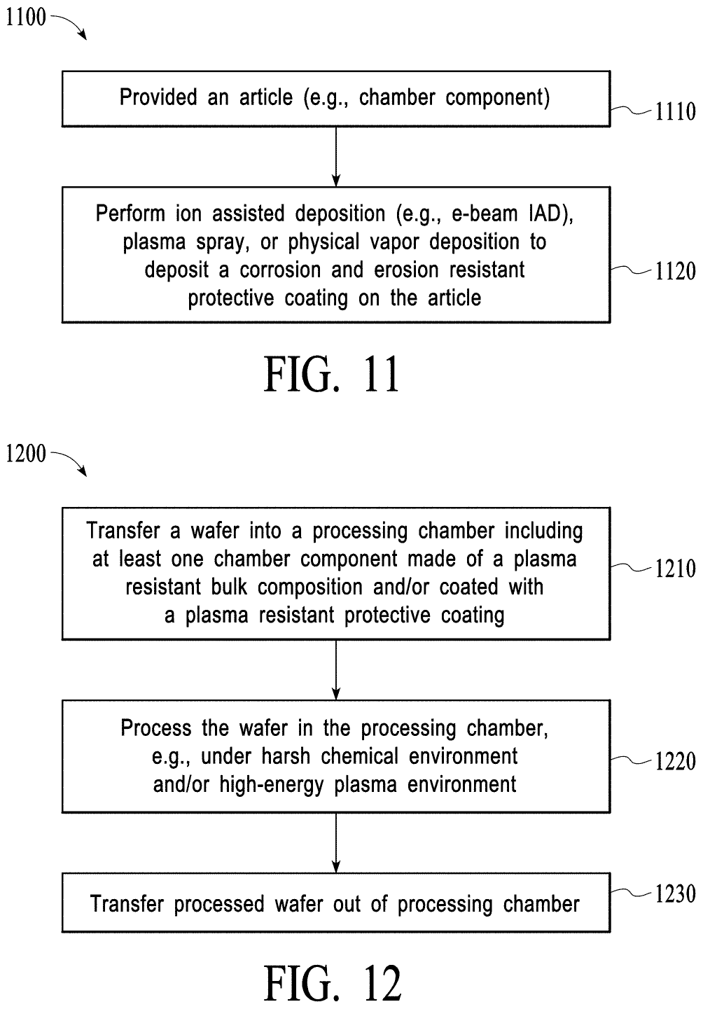

FIG. 11 illustrates one embodiment of a method 1100 for coating an article, such as a chamber component, with a plasma resistant protective coating according to an embodiment. At block 1110 of process 1100, an article, such as a chamber component, is provided. The chamber component (e.g., lid or a nozzle or a liner) may have a bulk sintered ceramic body having any of the bulk compositions described hereinbefore. Alternatively, the bulk sintered ceramic body may be Al₂O₃, Y₂O₃, SiO₂, or the ceramic compound comprising Y₄Al₂O₉ and a solid-solution of Y₂O₃—ZrO₂.

At block 1120, an ion assisted deposition (IAD) process (such as EB-IAD) or plasma spray or PVD is performed to deposit any of the corrosion resistant and erosion resistant plasma resistant protective coating described herein onto at least one surface of the chamber component. In one embodiment, an electron beam ion assisted deposition process (EB-IAD) is performed to deposit the plasma resistant protective coating. In one embodiment, plasma spray is performed to deposit the plasma resistant protective coating. In one embodiment, PVD is performed to deposit the plasma resistant protective coating.

In certain embodiments, the erosion resistant and corrosion resistant plasma resistant protective coating may be deposited by EB-IAD and may include a single phase amorphous blend of yttrium oxide at a molar concentration ranging from about 35 mole % to about 95 mole % and aluminum oxide at a molar concentration ranging from about 5 mole % to about 65 mole %. In certain embodiments, the plasma resistant protective coating includes yttrium oxide at a molar concentration ranging from 35 mole % to 40 mole % and aluminum oxide at a molar concentration ranging from 60 mole % to 65 mole %. In certain embodiments, the plasma resistant protective coating includes yttrium oxide at a molar concentration ranging from 37 mole % to 38 mole % and aluminum oxide at a molar concentration ranging from 62 mole % to 63 mole %.

The EB-IAD deposition process may be optimized to attain a plasma resistant coating having any of the compositions described herein and with any of the properties described herein such as, without limitations, 0% porosity, 100% amorphous, adhesion strength greater than about 25 MPa, a roughness of less than about 6 pin, a breakdown voltage of greater than about 2,500 V/mil, a hermeticity of less than about 3E-9, a hardness of about 8 GPa, a flexural strength of greater than about 400 MPa, stability at temperatures ranging from about 80° C. to about 120° C., chemical stability, or physical stability, to name a few.

In certain embodiments, the erosion resistant and corrosion resistant plasma resistant protective coating may be deposited by plasma spray or by physical vapor deposition and may include a substantially amorphous (e.g., greater than about 90% amorphous) blend of yttrium oxide at a molar concentration ranging from about 35 mole % to about 95 mole % and aluminum oxide at a molar concentration ranging from about 5 mole % to about 65 mole %. In certain embodiments, the plasma resistant protective coating includes yttrium oxide at a molar concentration ranging from 35 mole % to 40 mole % and aluminum oxide at a molar concentration ranging from 60 mole % to 65 mole %. In certain embodiments, the plasma resistant protective coating includes yttrium oxide at a molar concentration ranging from 37 mole % to about 38 mole % and aluminum oxide at a molar concentration ranging from 62 mole % to 63 mole %.

The physical vapor deposition or plasma spray deposition processes may be optimized to attain a plasma resistant coating having any of the compositions described herein and with any of the properties described herein such as, without limitations, greater than 90% amorphous, chemical stability, or physical stability, to name a few.

FIG. 12 illustrates a method 1200 for processing a wafer in a processing chamber that includes at least one chamber component that is made from any of the bulk compositions described herein and/or coated with any of the plasma resistant protective coatings described herein. Method 1200 includes transferring a wafer into a processing chamber that includes at least one chamber component (e.g., a lid, a liner, a door, a nozzle, and so on) made from any of the bulk compositions described herein and/or coated with any of the plasma resistant protective coatings described herein (1210). Method 1200 further includes processing the wafer in the processing chamber at a harsh chemical environment and/or a high energy plasma environment (1220). The processing environment may include halogen-containing gases and hydrogen-containing gases, such as C₂F₆, SF₆, SiCl₄, HBr, Br, NF₃, CF₄, CHF₃, CH₂F₃, F, NF₃, Cl₂, CCl₄, BCl₃, SiF₄, H₂, Cl₂, HCl, HF, among others, and other gases such as O₂, or N₂O. In one embodiment, the wafer may be processed in Cl₂. In one embodiments, the wafer may be processed in H₂. In one embodiment, the wafer may be processed in HBr. Method 1200 further includes transferring the processed wafer out of the processing chamber (1230).

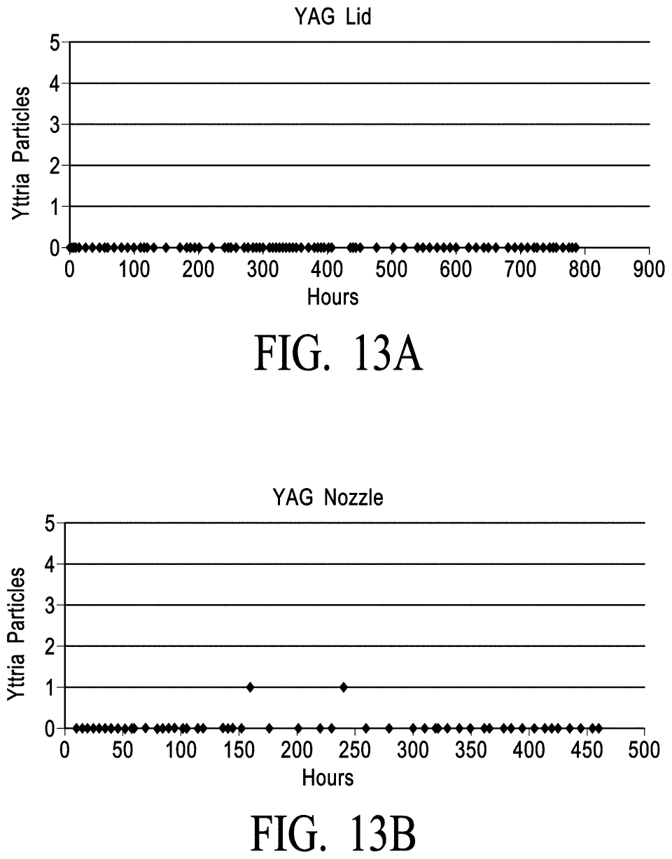

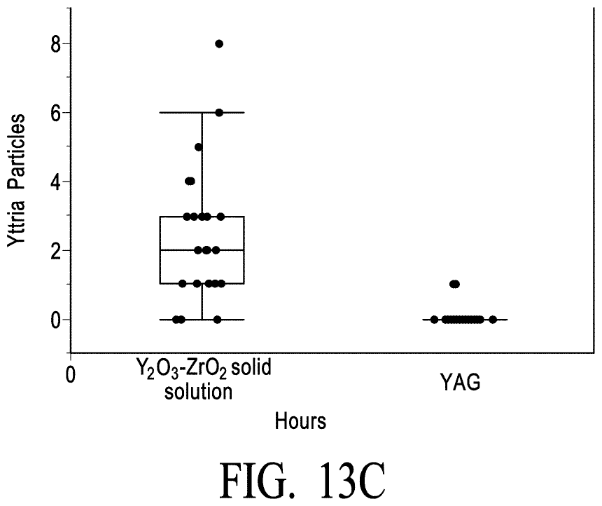

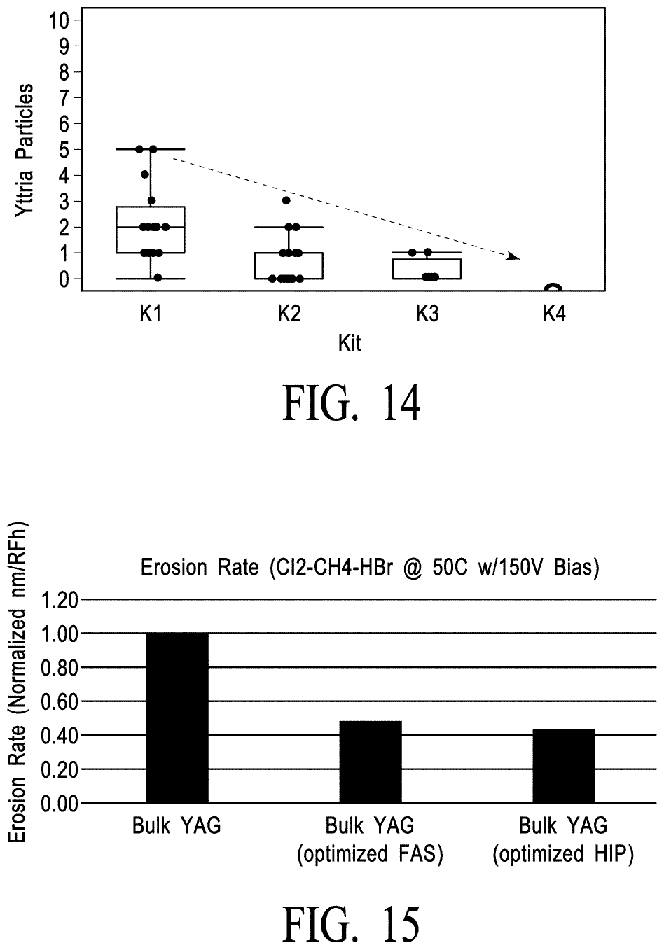

Wafers processed according to methods described herein in processing chambers having at least one chamber component made of any of the bulk compositions described herein and/or coated with a plasma resistant protective coating according to an embodiment exhibit a lower number of yttrium-based particle defects thereon as illustrated in FIGS. 13A-13C and 14. For instance, the average total number of yttrium based particles released from any of the plasma resistant protective coatings and/or from any of the bulk compositions described herein, upon exposure to corrosive chemistry, is less than about 3 per 500 radiofrequency hours (RFhrs), less than about 2 per 500 RFhrs, less than about 1 per 500 RFhrs, or zero per 500 RFhrs.

FIG. 13A depicts the number of yttrium based particles generated, after an extended processing duration under harsh chemical environment (running aggressive Cl₂, Hz, and fluorine based chemistry) and high energy plasma, by a lid that is made of bulk YAG according to an embodiment. Similar results were observed for lids coated with a YAG coating deposited by plasma spray, PVD, and IAD according to embodiments. As shown in FIG. 13A, after extended processing duration of about 770 radiofrequency hours (RFhrs), the number of yttrium based particles was zero. In other words, the lid passed 770 RFhrs with 100% zero yttrium based particles. In certain embodiments, the bulk compositions described herein and/or the coating compositions described herein have a high energy plasma resistance when exposed, for example, for a power of up to about 10,000 Watts for extended processing duration ranging from any of about 200 RFhrs, about 300 RFhrs, or about 400 RFhrs to any of about 500 RFhrs, about 600 RFhrs, about 700 RFhrs, or about 800 RFhrs, or any sub-range or single value therein.

FIG. 13B depicts the number of yttrium based particles generated, after an extended processing duration under harsh chemical environment (running aggressive Cl₂, Hz, and fluorine based chemistry) and high energy plasma, by a nozzle that is made of bulk YAG according to an embodiment. Similar results were observed for nozzles coated with a YAG coating deposited by plasma spray, PVD, and IAD according to embodiments. As shown in FIG. 13B, after extended processing duration of about 460 RFhrs, the number of yttrium based particles was two. In other words, the nozzle passed 460 RFhrs with greater than 95% zero yttrium based particles.

FIG. 13C depicts a comparison in performance with respect to the number of yttrium based particles generated, after an extended processing duration under harsh chemical environment and high energy plasma, by a kit of a nozzle and a lid according to an embodiment (e.g., each component being made of bulk YAG according to an embodiment, with similar results observed for components coated with a YAG coating deposited by plasma spray, PVD, and IAD according to embodiments) and a comparative kit of a comparative nozzle and a comparative lid (e.g., each component being made of bulk ceramic consisting of a Y₂O₃—ZrO₂ solid solution and/or coated with a coating consisting of a Y₂O₃—ZrO₂ solid solution deposited by plasma spray, PVD, or IAD).

Per FIG. 13C, the comparative kit (with comparative nozzle and comparative lid) resulted in many more yttrium based particles being generated, on average, during extended processing (e.g., about 500 RFhrs) as compared to a kit of a lid and a nozzle according to embodiments described herein. For instance, the average number of yttrium based particles generated during extended processing with a comparative kit ranged from about 1 to about 3 yttrium based particles (or from 0 to about 6 yttrium based particles with inclusion of the standard deviation). In comparison, the average number of yttrium based particles generated during extended processing with a kit according to embodiments described herein was zero.

Furthermore, per FIG. 13C, the comparative kit (with comparative nozzle and comparative lid) exhibited greater variation across processing occasions as compared to a kit of a lid and a nozzle according to embodiments described herein. For instance, the number of yttrium based particles generated during processing with a comparative kit varied, across a plurality of processing occasions, from zero to 8. “processing occasions” refers to processes (using a similar environment) which are conducted on different occasions (e.g., different times). In comparison, the number of yttrium based particles generated during processing with a kit according to embodiments described herein, across a plurality of processing occasions had substantially no variation.

Thus, in certain embodiments, processing wafers with kits according to embodiments described herein reduces the number of yttrium based particles that are generated, reduces wafer defectivity, increases accuracy, increases predictability, increases yield, increases throughput, and reduces cost.

Per FIG. 14, three comparative kits (with comparative nozzles, comparative lids, and comparative liners) resulted in more yttrium based particles being generated, on average, during extended processing (e.g., 500 RFhrs) as compared to a kit of a lid, a nozzle, and a liner having coatings and/or bulk compositions according to embodiments described herein. For instance, the average number of yttrium based particles generated during extended processing with a comparative kit (designated as K1 in FIG. 14) including chamber components coated or made of bulk ceramics consisting of a ceramic compound comprising Y₄Al₂O₉ and a solid-solution of Y₂O₃—ZrO₂ ranged from about 1 to about 2.5 yttrium based particles (or from 0 to about 5 yttrium based particles with inclusion of the standard deviation). The average number of yttrium based particles generated during extended processing with a comparative kit (designated as K2 in FIG. 14) including chamber components coated or made of bulk ceramics consisting of a Y₂O₃—ZrO₂ solid solution ranged from 0 to about 1 yttrium based particles (or from 0 to about 2 yttrium based particles with inclusion of the standard deviation). The average number of yttrium based particles generated during extended processing with a kit, designated as K3 in FIG. 14 (including a comparative nozzle consisting of a Y₂O₃—ZrO₂ solid solution coating or bulk composition, a comparative liner consisting of a ceramic compound comprising Y₄Al₂O₉ and a solid-solution of Y₂O₃—ZrO₂ coating or bulk composition, and a lid according to embodiments described herein), ranged from 0 to less than 1 yttrium based particles. The average number of yttrium based particles generated during processing with a kit (designated as K4 in FIG. 14) including a nozzle, a liner, and a lid according to embodiments described herein was zero.

Furthermore, per FIG. 14, the comparative kits consisting of a) a Y₂O₃—ZrO₂ solid solution and b) a ceramic compound comprising Y₄Al₂O₉ and a solid-solution of Y₂O₃—ZrO₂ exhibited greater variation across processing occasions as compared to a kit that included at least one component according to embodiments described herein. For instance, the number of yttrium based particles generated during processing with a comparative kit including chamber components coated with or made from a ceramic consisting of a ceramic compound comprising Y₄Al₂O₉ and a solid-solution of Y₂O₃—ZrO₂ varied, across a plurality of processing occasions, from zero to 5. The number of yttrium based particles generated during processing with a comparative kit including chamber components coated with or made from a ceramic consisting of a Y₂O₃—ZrO₂ solid solution varied, across a plurality of processing occasions, from zero to 3. In comparison, the number of yttrium based particles generated during processing with a kit including a nozzle consisting of a Y₂O₃—ZrO₂ solid solution, a liner consisting of a ceramic compound comprising Y₄Al₂O₉ and a solid-solution of Y₂O₃—ZrO₂, and a lid according to embodiments described herein, across a plurality of processing occasions, had significantly less yttrium based particles that were generated. Furthermore, a kit including a nozzle, a lid, and a liner according to embodiments described herein, across a plurality of processing occasions, had substantially no variation.

FIG. 15 depicts the normalized erosion rate (nm/RFhr) of a comparative bulk YAG composition (bulk YAG), a first optimized bulk YAG composition according to an embodiment (Bulk YAG1 (Optimized)) prepared via Field Assisted Sintering (FAS), and a second optimized bulk YAG composition according to an embodiment (Bulk YAG2 (Optimized)) prepared according to Hot Isotactic Pressing (HIP). The erosion rates were assessed after exposing the bulk compositions to Cl₂—CH₄—HBr at 50° C. with 150V Bias. The results depicted in FIG. 15 are also summarized in the table below. As can be seen from these results, bulk compositions according to the embodiments described herein exhibit enhanced erosion resistance as compared to other bulk YAG compositions prepared differently from the instant disclosure.

| Materials | Erosion/80 RFHrs | Erosion (nm/RFhrs) | Erosion Rate |
|---|---|---|---|
| Bulk YAG1 | 2.5 | 31.4 | 1.00 |
| Bulk YAG1 | 1.2 | 15.0 | 0.48 |
| (Optimized FAS) | | | |
| Bulk YAG2 | 1.1 | 13.8 | 0.44 |
| (Optimized HIP) | | | |

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±30%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A process chamber component comprising:
a ceramic body of the process chamber component, the ceramic body having at least an exterior facing surface comprising a crystalline yttrium aluminum garnet (YAG),
wherein the crystalline YAG comprises yttrium oxide at a molar concentration ranging from 35 mole % to 40 mole % and aluminum oxide at a molar concentration ranging from 60 mole % to 65 mole %, and
wherein the crystalline YAG has a density of about 98% or greater and a hardness greater than about 10 GPa.

2. The process chamber component of claim 1, wherein the crystalline YAG has less than 0.1% porosity.

3. The process chamber component of claim 1, wherein the crystalline YAG has a hardness greater than about 12 GPa.

4. The process chamber component of claim 1, wherein the ceramic body consists of the crystalline YAG, and wherein the crystalline YAG is a single phase bulk crystalline YAG.

5. The process chamber component of claim 1, wherein an average total number of yttrium based particles released from the crystalline YAG upon exposure to a corrosive chemistry is less than 3 per 500 radiofrequency hours.

6. The process chamber component of claim 5, wherein the corrosive chemistry comprises hydrogen based chemistry, halogen based chemistry, or a mixture thereof.

7. The process chamber component of claim 6, wherein the corrosive chemistry comprises one or more of HF, HBr, HCl, Cl₂, or H₂.

8. The process chamber component of claim 1, wherein the process chamber component comprises at least one of a lid, a nozzle, or a liner.

9. The process chamber component of claim 1, wherein the crystalline YAG is a result of a two-step sintering process comprising hot isotactic pressing (HIP).

10. A method of coating a process chamber component, comprising:
performing electron beam ion assisted deposition (e-beam IAD) to deposit a plasma resistant protective coating on at least a portion of a process chamber component,
wherein the plasma resistant protective coating comprises a single phase amorphous blend of yttrium oxide at a molar concentration ranging from about 35 mole % to about 95 mole % and aluminum oxide at a molar concentration ranging from about 5 mole % to about 65 mole %, and
wherein the plasma resistant protective coating has a porosity of 0% and an adhesion strength greater than about 25 MPa.

11. The method of claim 10, wherein the plasma resistant protective coating comprises a single phase amorphous blend of yttrium oxide at a molar concentration ranging from 35 mole % to 40 mole % and aluminum oxide at a molar concentration ranging from 60 mole % to 65 mole %.

12. The method of claim 11, wherein the plasma resistant protective coating comprises a single phase amorphous blend of yttrium oxide at a molar concentration ranging from 37 mole % to 38 mole % and aluminum oxide at a molar concentration ranging from 62 mole % to 63 mole %.

13. The method of claim 10, wherein the plasma resistant protective coating, at a thickness of 5 μm, has one or more of: a roughness of less than about 6 pin, a breakdown voltage of greater than about 2,500 V/mil, a hermeticity of less than about 3E-9, a hardness of about 8 GPa, a flexural strength of greater than about 400 MPa, or stability at temperatures ranging from about 80° C. to about 120° C.

14. The method of claim 10, wherein an average total number of yttrium based particles released from the plasma resistant protective coating upon exposure to a corrosive chemistry is less than 3 per 500 radiofrequency hours.

15. The method of claim 14, wherein the corrosive chemistry comprises a hydrogen-based chemistry, a halogen-based chemistry, or a mixture thereof.

16. The method of claim 15, wherein the corrosive chemistry comprises one or more of HF, HBr, HCl, Cl₂, or H₂.

17. A method of coating a process chamber component, comprising:
performing plasma spray or physical vapor deposition (PVD) to deposit a plasma resistant protective coating on a process chamber component,
wherein the plasma resistant protective coating comprises a blend of yttrium oxide at a molar concentration ranging from about 35 mole % to about 95 mole % and aluminum oxide at a molar concentration ranging from about 5 mole % to about 65 mole %,
wherein the plasma resistant protective coating is at least about 90% amorphous, and wherein an average total number of yttrium based particles released from the plasma resistant protective coating upon exposure to a corrosive chemistry is less than 3 per 500 radiofrequency hours.

18. The method of claim 17, wherein the plasma resistant protective coating comprises a blend of yttrium oxide at a molar concentration ranging from 35 mole % to 40 mole % and aluminum oxide at a molar concentration ranging from 60 mole % to 65 mole %.

19. The method of claim 18, wherein the plasma resistant protective coating comprises a blend of yttrium oxide at a molar concentration ranging from 37 mole % to 38 mole % and aluminum oxide at a molar concentration ranging from 62 mole % to 63 mole %.

20. The method of claim 19, wherein the corrosive chemistry comprises hydrogen based chemistry, halogen based chemistry, or a mixture thereof.
